(19) United States
(12) Patent Application Publication
(10) Pub. No.: US 2025/0089499 A1
(43) Pub. Date: Mar. 13, 2025

(54) DISPLAY DEVICE

(71) Applicant: Samsung Display Co., LTD., Yongin-si (KR)

(72) Inventors: HEEJU WOO, Yongin-si (KR); SEUNGJAE KANG, Yongin-si (KR); YOUNGMIN AHN, Yongin-si (KR)

(21) Appl. No.: 18/786,493

(22) Filed: Jul. 27, 2024

(30) Foreign Application Priority Data
Sep. 13, 2023 (KR) 10-2023-0121630

(51) Int. Cl. H10K 59/131; H10K 59/124

(52) U.S. Cl. CPC H10K 59/131; H10K 59/124

(57) ABSTRACT

A display device includes a pixel, a signal line electrically connected to the pixel, and a signal pad connected to the signal line. The signal pad includes a first conductive pattern disposed on the pad part, a second conductive pattern disposed on the first conductive pattern, and an insulating pattern, which, in a cross-section, is disposed between the pad part of the signal line and the second conductive pattern, and in a plan view, overlaps the second conductive pattern. The insulating pattern passes through the first conductive pattern via an upper reinforcement hole defined in the first conductive pattern.

This application claims priority to Korean Patent Application No. 10-2023-0121630, filed on Sep. 13, 2023, and all the benefits accruing therefrom under 35 U.S.C. § 119, the content of which in its entirety is herein incorporated by reference.

### BACKGROUND

### 1. Field

The disclosure herein relates to a display device and more particularly, to a pad region of a display device.

### 2. Description of the Related Art

A display device includes a display region which is activated in response to an electrical signal. The display device may detect an input applied from the outside through the display region and also display various images to provide information to a user.

The display device includes a display panel and a circuit board. The display panel may be connected to a main board through the circuit board. A driver chip may be mounted on the display panel.

### SUMMARY

The disclosure provides a display device with improved bonding reliability.

An embodiment of the inventive concept provides a display device including a display module, wherein the display module includes a pixel, a signal line including a line part and a pad part extending from one end of the line part, and electrically connected to the pixel, and a signal pad connected to the signal line, and the signal pad includes a first conductive pattern disposed on the pad part, a second conductive pattern disposed on the first conductive pattern, and an insulating pattern which, in a cross-section, is disposed between the pad part and the second conductive pattern, and in a plan view, overlaps the second conductive pattern, and a hole overlapping the insulating pattern in the plan view is defined in the first conductive pattern, and the insulating pattern passes through the first conductive pattern via the hole.

In an embodiment, a portion of a side surface of the insulating pattern may contact the first conductive pattern.

In an embodiment, the insulating pattern may protrude, from the first conductive pattern, toward a direction of getting farther away from the pad part.

In an embodiment, the first conductive pattern may have a structure of a plurality of layers.

In an embodiment, the second conductive pattern may contact at least a portion of an upper surface of the first conductive pattern, and a portion, of the insulating pattern, exposed from the first conductive pattern.

In an embodiment, in the cross-section, the second conductive pattern may further contact a portion, of an outer side surface of the first conductive pattern, opposed to an inner side surface which defines the hole.

In an embodiment, the display module may further include a first group insulating layer disposed between the pad part of the signal line and the first conductive pattern, a lower hole overlapping the hole in the plan view may be defined in the first group insulating layer, and the insulating pattern may pass through the first group insulating layer via the lower hole.

In an embodiment, the insulating pattern may contact a region, of the pad part of the signal line, overlapping the lower hole in the plan view.

In an embodiment, the display module may further include a first group insulating layer disposed between the pad part of the signal line and the first conductive pattern, a first contact hole, which, in the plan view, overlaps the pad part of the signal line and is spaced apart from the insulating pattern, may be defined in the first group insulating layer, and the first conductive pattern may contact the pad part of the signal line via the first contact hole.

In an embodiment, the first conductive pattern may include a contact portion and a recessed portion having a smaller width than a width of the contact portion in one direction, the first contact hole may overlap the contact portion, and the hole may be defined in the recessed portion.

In an embodiment, the display module may further include a second group insulating layer disposed between the first conductive pattern and the second conductive pattern, and having a second contact hole defined therein, and in the plan view, the first contact hole and the insulating pattern may be disposed inside the second contact hole.

In an embodiment, the pixel may include: a light-emitting element; a transistor electrically connected to the light-emitting element and including a semiconductor pattern and a gate overlapping the semiconductor pattern; an upper electrode disposed on the gate; and a plurality of connection electrodes electrically connected to the transistor and disposed in different layers, and the pad part of the signal line comprises a same material as that of the gate or the upper electrode, and the first conductive pattern may include a same material as at least one of the plurality of connection electrodes.

In an embodiment, the display module may further include: a lower insulating layer disposed between the semiconductor pattern and the gate; an intermediate insulating layer disposed between the gate and the upper electrode; and an upper insulating layer disposed between the upper electrode and the plurality of connection electrodes, and the first group insulating layer may include the lower insulating layer, the intermediate insulating layer, and the upper insulating layer.

In an embodiment, the display module may further include: a thin-film encapsulation layer disposed on the pixel; and a sensing electrode disposed on the thin-film encapsulation layer, and the second conductive pattern comprises a same material as that of the sensing electrode.

In an embodiment, the display module may further include a second group insulating layer disposed between the first conductive pattern and the second conductive pattern, and the second conductive pattern and the sensing electrode may contact the second group insulating layer.

In an embodiment, the insulating pattern may be provided in plural, a plurality of holes may be provided in the first conductive pattern, and the plurality of holes may respectively overlap the insulating patterns in the plan view.

In an embodiment, the insulating pattern may include a polymer.

In an embodiment, the display device may further include an electronic component electrically connected to the display module; and an adhesive layer disposed between the display module and the electronic component, wherein a portion, of the second conductive pattern, overlapping the insulating pattern may contact the electronic component.

In an embodiment, the electronic component may include a substrate, and a bump electrode disposed below the substrate, and a portion, of the second conductive pattern, overlapping the insulating pattern contacts the bump electrode.

In an embodiment, the electronic component may include a driver chip or a circuit board.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an embodiment of a display device according to the inventive concept;

FIGS. 2A and 2B are exploded perspective views of an embodiment of a display device according to the inventive concept;

FIG. 3 is a cross-sectional view of an embodiment of a display module according to the inventive concept;

FIG. 4 is a plan view of an embodiment of a display panel according to the inventive concept;

FIG. 5 is a cross-sectional view of an embodiment of one pixel according to the inventive concept;

FIG. 6A is a cross-sectional view of an embodiment of an input sensor according to the inventive concept;

FIG. 6B is a plan view of an embodiment of an input sensor according to the inventive concept;

FIG. 6C is a cross-sectional view of an embodiment of a bridge pattern of an input sensor along line X-X′ of FIG. 6B according to the inventive concept;

FIG. 7 is an enlarged exploded perspective view of an embodiment of a pad region of a display device according to the inventive concept;

FIG. 8A is a schematic plan view of an embodiment of a pad region according to the inventive concept;

FIGS. 8B to 8E are plan views illustrating an embodiment of some components inside a pad region according to the inventive concept;

FIGS. 9A to 9D are cross-sectional views corresponding to that of FIG. 8A;

FIG. 10 is a cross-sectional view illustrating an embodiment of a bonding structure of a display device according to the inventive concept;

FIGS. 11A to 11C are cross-sectional views which illustrate an embodiment of some operations of a method of manufacturing a display device according to the inventive concept;

FIG. 12A is a schematic plan view of an embodiment of a pad region according to the inventive concept;

FIG. 12B is a plan view illustrating an embodiment of some components inside a pad region according to the inventive concept; and

FIG. 13 is a cross-sectional view corresponding to that of FIG. 12A.

### DETAILED DESCRIPTION

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. Also, in the drawings, the thickness, the ratio, and the dimension of the elements are exaggerated for effective description of the technical contents. The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms, unless the context clearly indicates otherwise.

Also, the terms such as “below”, “lower”, “above”, “upper” and the like, may be used for describing a relationship of elements illustrated in the drawing figures. It will be understood that the terms have a relative concept and are described on the basis of the orientation depicted in the drawing figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the inventive concept will be described with reference to the accompanying drawings.

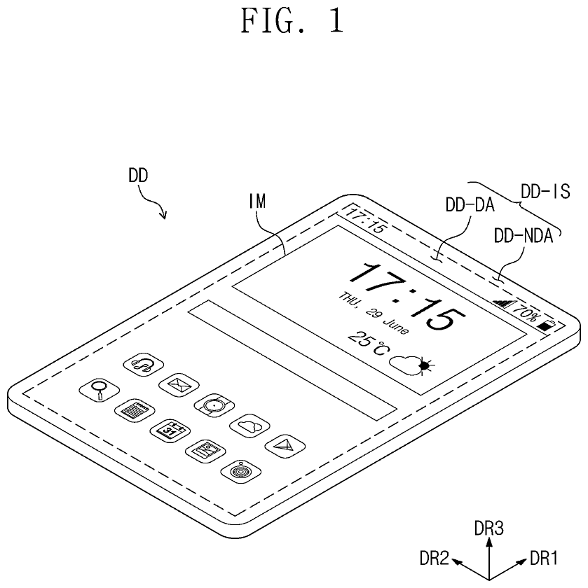

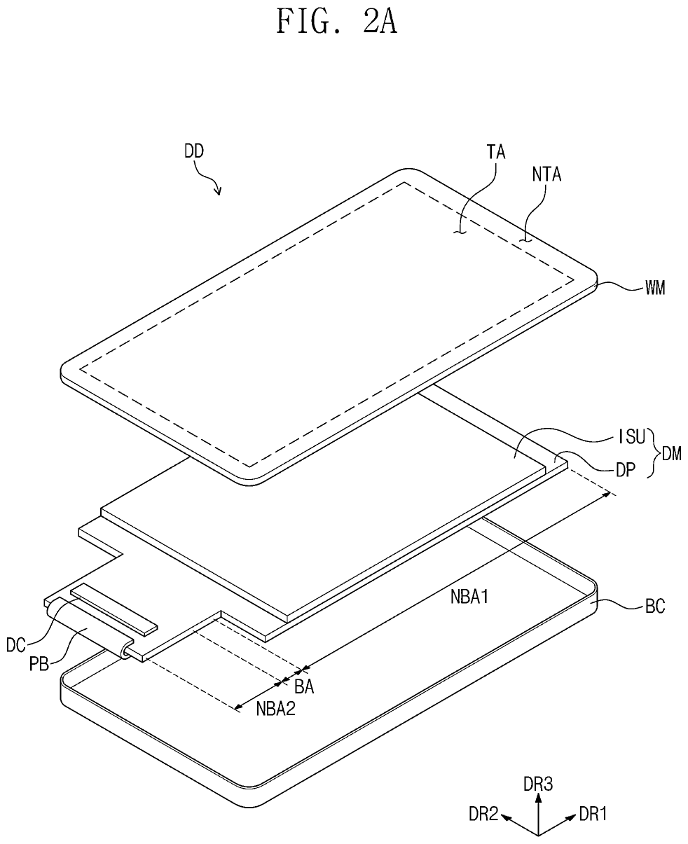

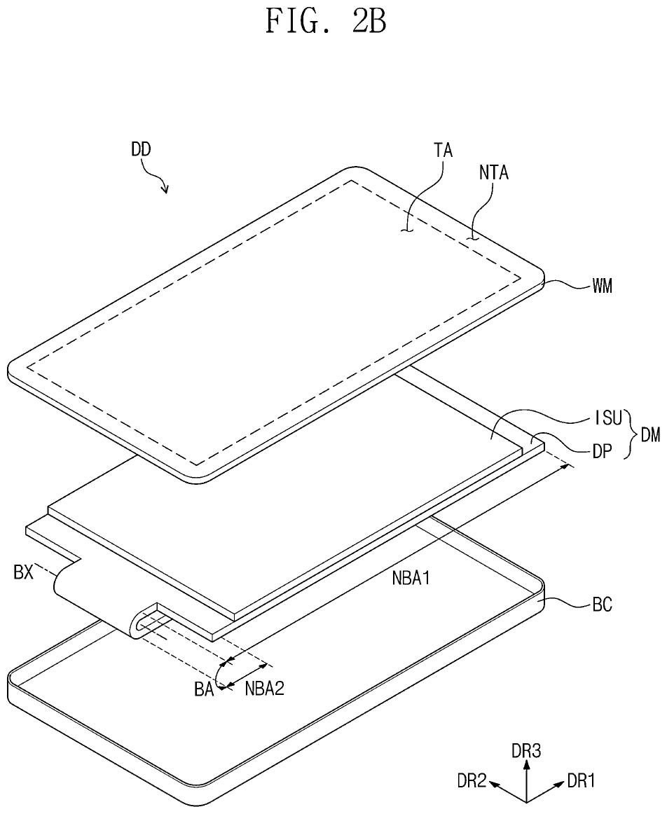

FIG. 1 is a perspective view of an embodiment of a display device DD according to the inventive concept. FIGS. 2A and 2B are exploded perspective views of an embodiment of a display device DD according to the inventive concept.

FIG. 2B illustrates a state in which a bending region BA illustrated in FIG. 2A is bent, for example.

Referring to FIG. 1, in this specification, the display device DD is illustrated as a cellular phone terminal. The display device DD according to the inventive concept may be applied to a small-sized and medium-sized electronic device such as a tablet computer, a car navigation system, a game console, and a smart watch, as well as a large-sized electronic device such as a television and a monitor.

The display device DD may have a quadrangular shape, e.g., rectangular shape, which has long sides extending in a first direction DR1 and short sides extending in a second direction DR2 crossing the first direction DR1. However, the inventive concept is not limited thereto, and in a plan view, the display device DD may have various shapes, such as a circular or polygonal shape.

Hereinafter, a direction which is substantially perpendicular to a plane defined by the first direction DR1 and the second direction DR2 is defined as a third direction DR3. In this specification, the wording “in a plan view” may mean a view in the third direction DR3.

The display device DD may be rigid or flexible. The wording “flexible” means a bendable property, and may include all of a completely foldable structure as well as a structure which is bendable to the level of several nanometers. In an embodiment, a flexible display device DD may include a curved electronic device, a rollable electronic device, or a foldable display device, for example.

The display device DD may display an image IM through a display surface DD-IS. Icon images are illustrated as the image IM. The display surface DD-IS may be parallel to a surface defined by the first direction DR1 and the second direction DR2.

The display surface DD-IS may include a display region DD-DA in which the image IM is displayed and a non-display region DD-NDA adjacent to the display region DD-DA. The non-display region DD-NDA may be a region in which an image is not displayed. However, the inventive concept is not limited thereto, and the non-display region DD-NDA may be adjacent to any one side of the display region DD-DA or may be omitted.

Referring to FIGS. 2A and 2B, the display device DD may include a window WM, a display module DM, and an accommodation member BC.

The window WM may be disposed above the display module DM, and transmit, to the outside, an image provided from the display module DM. The window WM may include a transmission region TA and a non-transmission region NTA. The transmission region TA may overlap the display region DD-DA illustrated in FIG. 1, and have a shape corresponding to that of the display region DD-DA. Although not illustrated, the window WM may include a base layer and functional layers disposed on the base layer. The functional layers may include a protective layer, an anti-fingerprint layer, or the like. The base layer of the window WM may include or consist of glass, sapphire, plastic, or the like. The base layer of the window WM may include an optically transparent insulating material. In an embodiment, the base layer of the window WM may include glass or a plastic film, or may include a glass substrate and a plastic film which are bonded via an adhesive agent, for example.

The non-transmission region NTA may overlap the non-display region DD-NDA illustrated in FIG. 1, and have a shape corresponding to that of the non-display region DD-NDA. The non-transmission region NTA may be a region having a relatively lower light transmittance than the transmission region TA. The non-transmission region NTA may be defined by disposing a bezel pattern in a partial region of the base layer of the window WM, and the transmission region TA may be defined as a region in which the bezel pattern is not disposed. However, the inventive concept is not limited thereto, and the non-transmission region NTA may be omitted.

Although not illustrated, an anti-reflection layer may be disposed between the window WM and the display module DM. The anti-reflection layer may reduce reflectance for external light incident from the outside of the display device DD. The anti-reflection layer may include color filters. The color filters may have a predetermined arrangement. In an embodiment, the color filters may be disposed in consideration of emission colors of pixels included in a display panel DP to be described later, for example. Additionally, the anti-reflection layer may further include a black matrix adjacent to the color filters.

In an embodiment of the inventive concept, the display module DM may include the display panel DP and an input sensor ISU.

The display panel DP may be any one among a liquid crystal display panel, an electrophoretic display panel, a microelectromechanical system (“MEMS”) display panel, an electrowetting display panel, an organic light-emitting display panel, an inorganic light-emitting display panel, and a quantum dot light-emitting display panel. However, an embodiment of the inventive concept may not be particularly limited thereto. Hereinafter, the display panel DP is described as an organic light-emitting display panel.

The input sensor ISU may include any one among a capacitive sensor, an optical sensor, an ultrasonic sensor, and an electromagnetic induction sensor. The input sensor ISU may be formed on the display panel DP through a continuous process, or may be manufactured separately and then attached to an upper side of the display panel DP via an adhesive layer, but is not limited to a particular embodiment.

The display device DD may further include a driver chip DC disposed on the display panel DP. The display device DD may further include a circuit board PB disposed on the display panel DP. In this embodiment, the circuit board PB may be a flexible circuit board, but is not limited thereto. In an embodiment, the circuit board PB may be rigid, for example. The circuit board PB may electrically connect the display panel DP and a main circuit board.

The driver chip DC may include driving elements for driving pixels of the display panel DP, e.g., a data driving circuit. FIG. 2A illustrates a structure in which the driver chip DC is disposed (e.g., mounted) on the display panel DP, but the inventive concept is not limited thereto. In an embodiment, the driver chip DC may also be disposed (e.g., mounted) on the circuit board PB, for example. In this embodiment, the driver chip DC and the circuit board PB which are directly disposed (e.g., mounted) on the display panel DP may be collectively referred to as electronic components. Hereinafter, the description of a bonding structure of the display panel DP and the circuit board PB may also be similarly applied to another electronic component such as the driver chip DC in addition to the circuit board PB.

The display panel DP may include a bending region BA, and a first non-bending region NBA1 and a second non-bending region NBA2 which are spaced apart from each other in the first direction DR1 with the bending region BA therebetween.

The bending region BA may be defined as a region in which the display panel DP is bent with respect to an imaginary bending axis BX extending in the second direction DR2. The first non-bending region NBA1 may be defined as a region overlapping the transmission region TA, and the second non-bending region NBA2 may be defined as a region to which the circuit board PB is connected. When the bending region BA is bent with respect to the bending axis BX, the circuit board PB and the driver chip DC may be bent toward a rear surface of the display panel DP and be disposed below the rear surface of the display panel DP. Although not illustrated, additional components may be disposed to compensate for a step which is caused by the bending region BA and is formed between the circuit board PB and a rear surface of the display panel DP.

In an embodiment, in the first direction DR1, the width of the first non-bending region NBA1 may be greater than the widths of the bending region BA and the second non-bending region NBA2. However, the inventive concept is not limited thereto, and the bending region BA may be provided in a shape such that the width of the bending region BA in the first direction DR1 becomes narrower from the first non-bending region NBA1 toward the second non-bending region NBA2. The bending region BA is not limited to a particular embodiment.

As illustrated in FIG. 2B, a portion of the display panel DP is bent, so that the circuit board PB electrically bonded to the display panel DP may be disposed on a rear surface of the display panel DP.

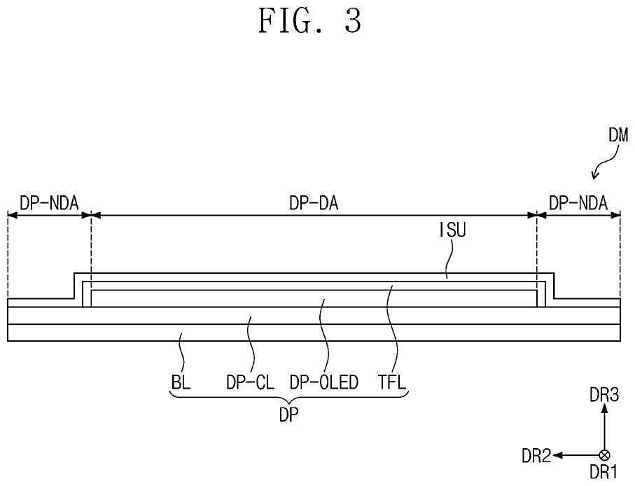

The accommodation member BC may accommodate the display module DM and be coupled to the window WM. The circuit board PB may be disposed on one end of the display panel DP and electrically connected to a circuit element layer DP-CL to be described in FIG. 3. Although not illustrated, the display device DD may further include a main board, electronic modules disposed (e.g., mounted) on the main board, a camera module, a power module, or the like.

The display device DD described above is illustrated as a cellular phone terminal, but in this specification, the display device DD may be any device constituted by including two or more bonded electronic components. The display panel DP and the driver chip DC disposed (e.g., mounted) on the display panel DP respectively correspond to different electronic components, and the display device DD may be constituted by only these components. The display panel DP and the circuit board PB disposed (e.g., mounted) on the display panel DP respectively correspond to different electronic components, and the display device DD may be constituted by only these components. Additionally, the display device DD may be constituted by only a main board and electronic modules disposed (e.g., mounted) on the main board. Hereinafter, the following description of the display device DD according to the inventive concept will be mainly focused on a bonding structure of the display panel DP and the driver chip DC disposed (e.g., mounted) on the display panel DP.

FIG. 3 is a cross-sectional view of an embodiment of a display module DM according to the inventive concept.

Referring to FIG. 3, a display panel DP may include a base layer BL, a circuit element layer DP-CL disposed on the base layer BL, a display element layer DP-OLED, and an upper insulating layer TFL. An input sensor ISU may be disposed on the upper insulating layer TFL.

The display panel DP may include a display region DP-DA and a non-display region DP-NDA. The display region DP-DA of the display panel DP may correspond to the display region DD-DA illustrated in FIG. 1 or the transmission region TA illustrated in FIG. 2A, and the non-display region DP-NDA may correspond to the non-display region DD-NDA illustrated in FIG. 1 or the non-transmission region NTA illustrated in FIG. 2A.

The base layer BL may include at least one plastic film. The base layer BL may include, as a flexible substrate, a plastic substrate, a glass substrate, a metal substrate, an organic/inorganic composite material substrate, or the like.

The circuit element layer DP-CL may include at least one intermediate insulating layer or a circuit element layer. The intermediate insulating layer may include at least one intermediate inorganic layer or at least one intermediate organic layer. The circuit element may include signal lines, a pixel driving circuit, or the like. An insulating layer, a semiconductor layer, and a conductive layer are formed through coating, deposition, or the like. Thereafter, the insulating layer, the semiconductor layer, and the conductive layer may be selectively patterned by performing a photolithography process and an etching process. In this process, a semiconductor pattern, a conductive pattern, a signal line, etc., are formed. Patterns disposed in the same layer are formed through the same process. Hereinafter, the wording “patterns are formed through the same process” means that the patterns include the same material and have the same stacked structure.

The display element layer DP-OLED may include a plurality of light-emitting elements. The display element layer DP-OLED may further include an organic layer such as a pixel-defining layer.

The upper insulating layer TFL may seal the display element layer DP-OLED. The upper insulating layer TFL may be disposed on the display element layer DP-OLED. The upper insulating layer TFL may overlap a display region DP-DA and a non-display region DP-NDA. The upper insulating layer TFL may overlap at least a portion of the non-display region DP-NDA. In an embodiment, the upper insulating layer TFL may include a thin-film encapsulation layer, for example. The thin-film encapsulation layer may have a stacked structure of an inorganic layer/an organic layer/an inorganic layer. The upper insulating layer TFL may protect the display element layer DP-OLED against moisture, oxygen, and foreign substances such as dust particles. However, the inventive concept is not limited thereto, and the upper insulating layer TFL may further include an additional insulating layer in addition to the thin-film encapsulation layer. In an embodiment, an optical insulating layer for controlling a refractive index may be further included, for example.

In an embodiment of the inventive concept, an encapsulation substrate may be provided instead of the upper insulating layer TFL. In this case, the encapsulation substrate may face the base layer BL, and the circuit element layer DP-CL and the display element layer DP-OLED may be disposed between the encapsulation substrate and the base layer BL.

The input sensor ISU may be directly disposed on the display panel DP. In this specification, the wording, “an A component being directly disposed on a B component” means that another layer is not disposed between the A component and the B component. In this embodiment, the input sensor ISU and the display panel DP may be manufactured through a continuous process. However, the idea of the inventive concept is not limited thereto, and the input sensor ISU may be provided as a separate panel and coupled to the display panel DP via the adhesive layer. In an embodiment, the input sensor ISU may be omitted.

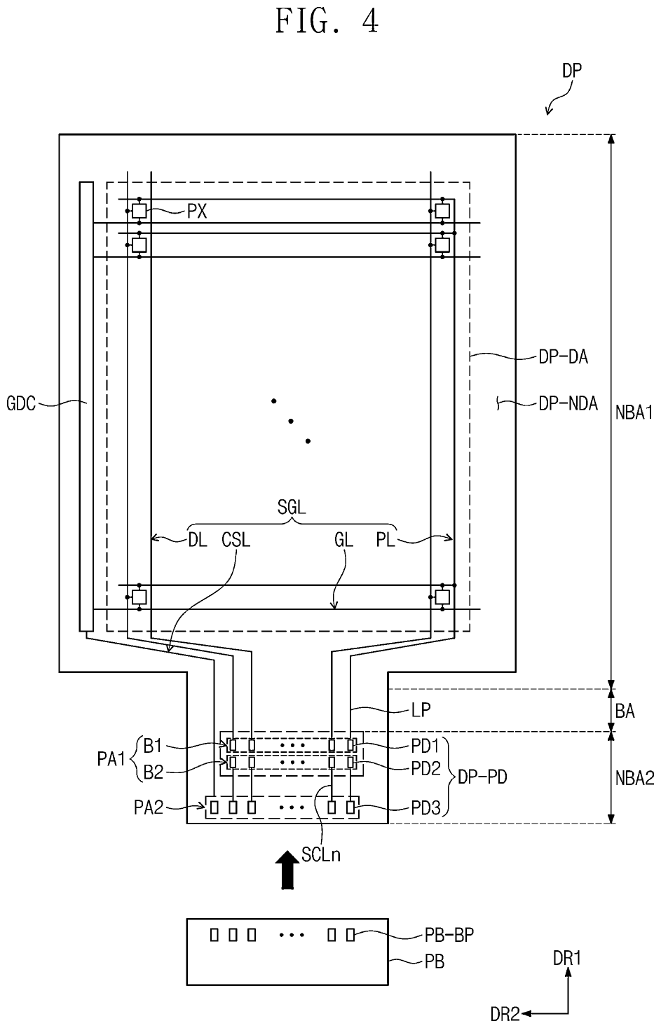

FIG. 4 is a plan view of an embodiment of a display panel DP according to the inventive concept.

Referring to FIG. 4, the display panel DP may include a plurality of pixels PX, a gate driving circuit GDC, a plurality of signal lines SGL, and a plurality of signal pads DP-PD.

The pixels PX may be disposed in a display region DP-DA. The pixels PX each include a light-emitting element and a pixel driving circuit connected thereto. In an embodiment, a light-emitting element may be an organic light-emitting element. The gate driving circuit GDC sequentially outputs gate signals to a plurality of gate lines GL to be described later. A transistor of the gate driving circuit GDC may be formed through the same process as a transistor of the pixel PX, e.g., a low temperature polycrystalline silicon (“LTPS”) process or a low temperature polycrystalline oxide (“LTPO”) process. The display panel DP may further include another driving circuit which provides a light-emitting control signal to the pixels PX.

The signal lines SGL may include gate lines GL, data lines DL, a power line PL, and a control signal line CSL. The gate lines GL may be respectively connected to corresponding pixels PX among the pixels PX, and the data lines DL may be respectively connected to corresponding pixels PX among the pixels PX. The power line PL may be connected to the pixels PX. The control signal line CSL may provide control signals to a scan driving circuit.

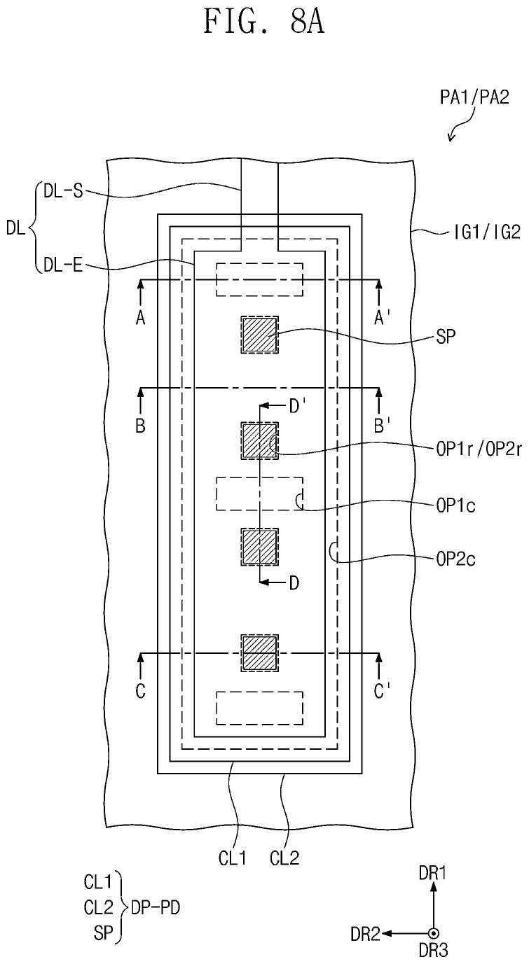

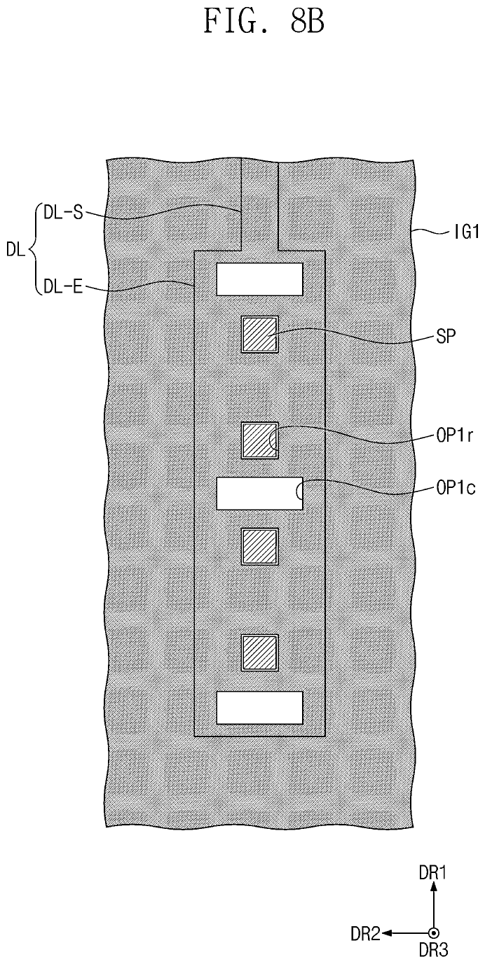

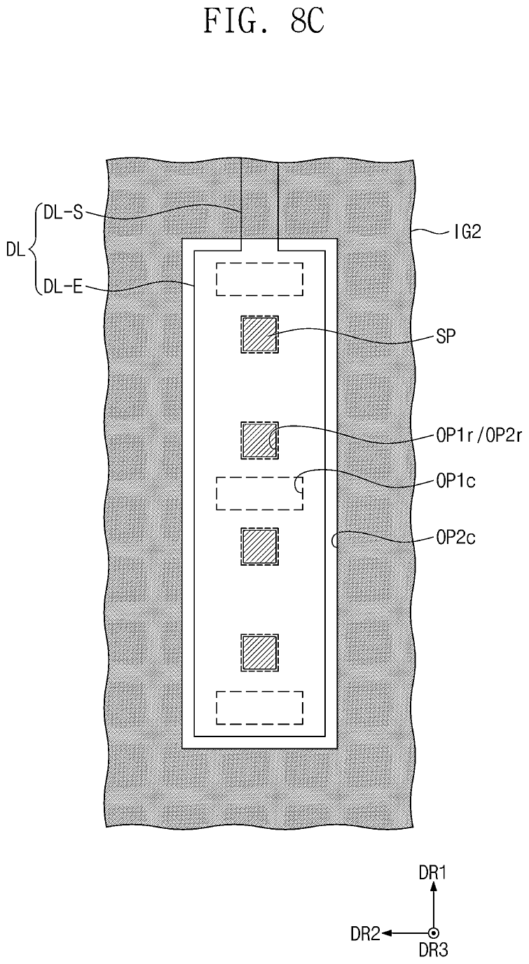

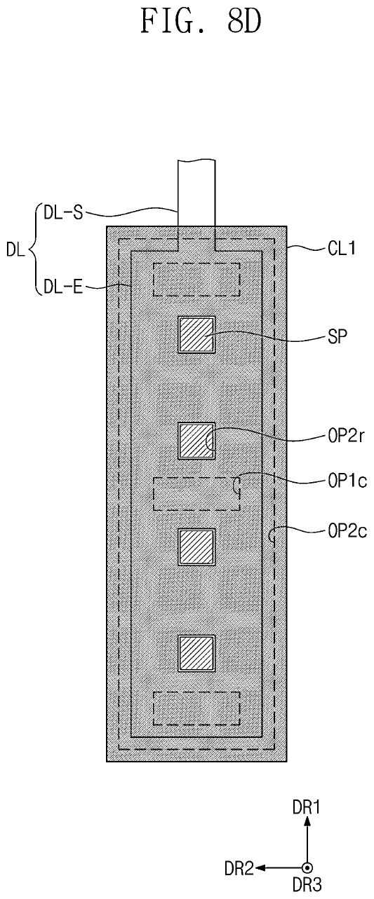

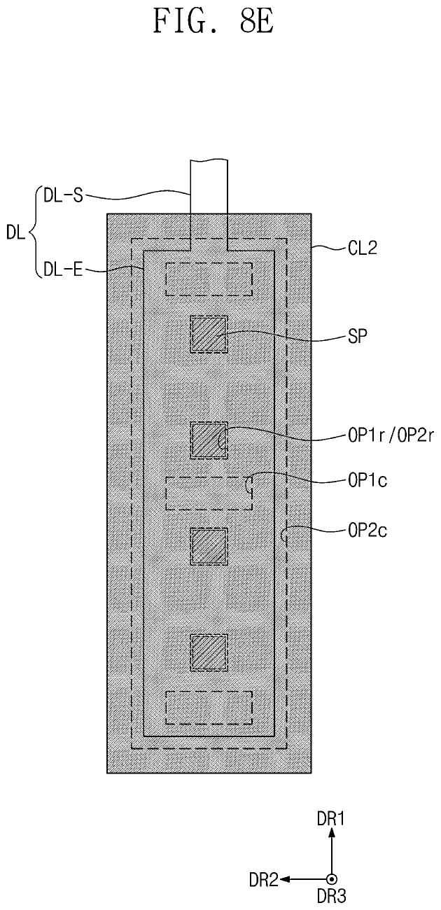

The signal lines SGL may overlap the display region DP-DA and a non-display region DP-NDA. The signal lines SGL may each include a wire part LP. Although not illustrated, the signal lines SGL may further include a pad part. The wire part LP may overlap the display region DP-DA and the non-display region DP-NDA. The pad part may be connected to a terminal of the wire part LP. In an alternative embodiment, the pad part may extend from one end of the wire part LP. The connection of the pad part and the wire part LP will be described in FIG. 8A in more detail.

A plurality of signal pads DP-PD may include first pads PD1, second pads PD2, and third pads PD3. A region in which the first and second pads PD1 and PD2 are disposed may be defined as a first pad region PA1, and a region in which the third pads PD3 are disposed may be defined as a second pad region PA2.

The first pad region PA1 may be a region overlapping the driver chip DC of FIG. 2A, and the second pad region PA2 may be a region overlapping a circuit board PB. The first pad region PA1 may include a first region B1 in which the first pads PD1 are disposed, and a second region B2 in which the second pads PD2 are disposed. The first pad region PA1 and the second pad region PA2 may be disposed inside the non-display region DP-NDA. The first pad region PA1 and the second pad region PA2 may be spaced apart from each other in the first direction DR1. It is illustrated that one pad row is disposed in the first pad region PA1, but the inventive concept is not limited thereto. A plurality of pad rows may be disposed in the first pad region PA1.

The first pads PD1 may be respectively connected to corresponding data lines DL among the data lines DL. Although not illustrated, the first pads PD1 and the second pads PD2 may be electrically connected to each other. The second pads PD2 may be connected to the third pads PD3 via connection signal lines SCLn.

The circuit board PB may include a plurality of substrate bump electrodes PB-BP. The substrate bump electrodes PB-BP may be arranged along the second direction DR2. The substrate bump electrodes PB-BP of the circuit board PB may be connected to contact the third pads PD3 in the second pad region PA2.

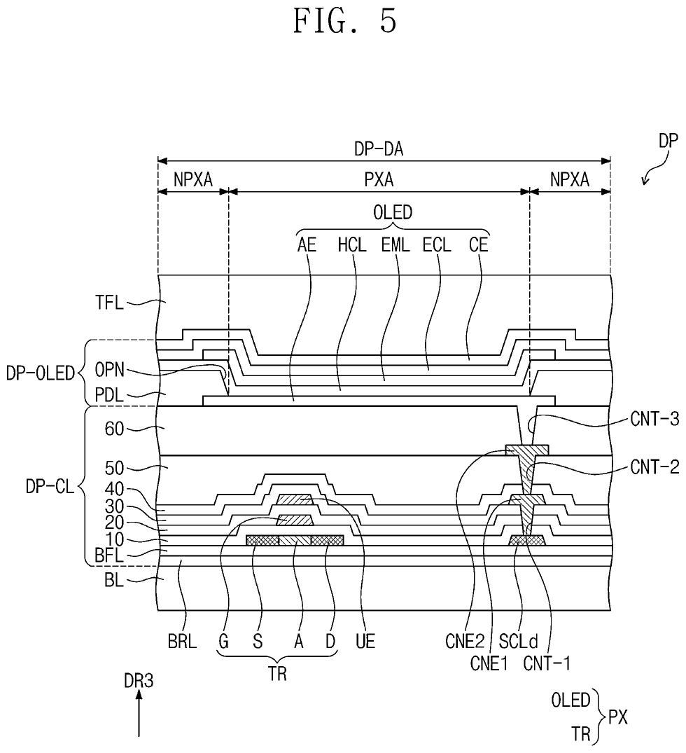

FIG. 5 is a cross-sectional view of one pixel according to the inventive concept.

Referring to FIGS. 4 and 5, the display region DP-DA may include a light-emitting region PXA and a non-light-emitting region NPXA. The pixels may each include a light-emitting element OLED and a pixel driving circuit connected thereto. In an embodiment, the pixel PX may include a transistor TR and an organic light-emitting element (e.g., organic light-emitting diode) OLED.

FIG. 5 illustrates one transistor TR, but the inventive concept is not limited thereto. The pixel PX in an embodiment may include seven transistors and at least one capacitor, and the seven transistors and the capacitor may be electrically connected to each other. However, the number of transistors and the number of capacitors constituting the pixel PX is not limited to a particular embodiment.

The display panel DP may include a plurality of insulating layers, a semiconductor pattern, a conductive pattern, a signal line, or the like. An insulating layer, a semiconductor layer, and a conductive layer are formed through coating, deposition, or the like. Thereafter, the insulating layer, the semiconductor layer, and the conductive layer may be selectively patterned by performing a photolithography process. In this manner, the semiconductor pattern, the conductive pattern, and the signal line, included in the circuit element layer DP-CL and the display element layer DP-OLED, are formed.

A base layer BL may include a synthetic resin film. The base layer BL may have a multi-layered structure. In an embodiment, the base layer BL may also have a three-layered structure of a synthetic resin layer, an inorganic layer, and a synthetic resin layer, for example. In particular, the synthetic resin layer may be a polyimide-based resin layer, and materials thereof are not particularly limited. Additionally, the base layer BL may include a glass substrate, a metal substrate, an organic/inorganic composite material substrate, or the like.

In an embodiment, the circuit element layer DP-CL may include a barrier layer BRL, a buffer layer BFL, first to sixth insulating layers 10 to 60, a transistor TR, a connection signal line SCLd, an upper electrode UE, a first connection electrode CNE1, and a second connection electrode CNE2.

At least one inorganic layer is disposed on an upper surface of the base layer BL. The inorganic layer may be formed as a multi-layer. The barrier layer BRL may be disposed on the base layer BL. The buffer layer BFL may be disposed on the barrier layer BRL. The barrier layer BRL and the buffer layer BFL may be inorganic layers.

A semiconductor pattern is disposed on the buffer layer BFL. The semiconductor pattern may include polysilicon. However, the semiconductor pattern is not limited thereto, and may include amorphous silicon, or a metal oxide.

FIG. 5 merely illustrates a portion of a semiconductor pattern but a semiconductor pattern may be further disposed in another region of the pixel PX in a plan view. The semiconductor pattern may be disposed across pixels in accordance with the predetermined pattern. The electrical properties of the semiconductor pattern vary depending on whether to be doped or not. The semiconductor pattern may include a first region and a second region. The first region may be doped with an N-type dopant or a P-type dopant. A P-type transistor includes a doped region doped with a P-type dopant.

The first region has higher conductivity than the second region and substantially serves as an electrode or a signal line. The second region may have a lower doping concentration, or may be an undoped region. Substantially, the second region corresponds to an active (or channel) of a transistor. That is, a portion of the semiconductor pattern may be an active of a transistor, another portion may be a source or drain of a transistor, and another portion may be a connection electrode or connection signal line.

As illustrated in FIG. 5, a source S, an active A, and a drain D of a transistor TR are formed from the semiconductor pattern.

FIG. 5 illustrates a portion of a connection signal line SCLd formed from the semiconductor pattern. In an embodiment, the connection signal line SCLd may be electrically connected to any one drain among the transistors inside the pixel PX.

A first insulating layer 10 is disposed on a buffer layer BFL. The first insulating layer 10 may cover the semiconductor pattern. The first insulating layer 10 may overlap the plurality of pixels in common. A gate G is disposed on the first insulating layer 10. The gate G may be a portion of a metal pattern. The gate G may overlap the active A. During the process of doping the semiconductor pattern, the gate G may function as a mask.

A second insulating layer 20 covering the gate G may be disposed on the first insulating layer 10. The second insulating layer 20 may overlap the pixels in common. An upper electrode UE may be disposed on the second insulating layer 20. The upper electrode UE may overlap the gate G of the transistor TR. The upper electrode UE may be a portion of a metal pattern. A portion of the gate G and the upper electrode UE overlapping the portion may define a capacitor.

A third insulating layer 30 covering the upper electrode UE may be disposed on the second insulating layer 20. A first connection electrode CNE1 disposed on the third insulating layer 30 may be connected to a connection signal line SCLd via a contact hole CNT-1 passing through the first to third insulating layers 10 to 30.

A fourth insulating layer 40 covering the first connection electrode CNE1 may be disposed on the third insulating layer 30. The first to fourth insulating layers 10 to 40 may each be an inorganic layer and/or an organic layer, and have a single- or multi-layered structure.

The first connection electrode CNE1 may be disposed on the fourth insulating layer 40 and be covered by a fifth insulating layer 50. In an alternative embodiment, in an embodiment of the inventive concept, both of the first connection electrode, which is disposed on the third insulating layer 30 and covered by the fourth insulating layer 40, and the first connection electrode, which is disposed on the fourth insulating layer 40 and covered by the fifth insulating layer 50, may be included.

The fifth insulating layer 50 may be disposed on the fourth insulating layer 40. The fifth insulating layer 50 may be an organic layer. A second connection electrode CNE2 may be disposed on the fifth insulating layer 50. The second connection electrode CNE2 may be connected to the first connection electrode CNE1 via a contact hole CNT-2 passing through the fourth insulating layer 40 and the fifth insulating layer 50.

A sixth insulating layer 60 covering the second connection electrode CNE2 may be disposed on the fifth insulating layer 50. The sixth insulating layer 60 may be an organic layer. A first electrode AE may be disposed on the sixth insulating layer 60. The first electrode AE may be connected to the second connection electrode CNE2 via a contact hole CNT-3 passing through the sixth insulating layer 60.

The circuit element layer DP-CL may include a plurality of connection electrodes connected to the transistors, and some of the plurality of connection electrodes may be disposed in different layers. Although not illustrated, the first connection electrode CNE1 may extend to be connected to the transistor TR. A position of the plurality of connection electrodes is not limited to a particular embodiment.

The display element layer DP-OLED may include a pixel-defining layer PDL and a light-emitting element OLED. A pixel opening OPN may be defined in the pixel-defining layer PDL. The pixel opening OPN of the pixel-defining layer PDL may expose at least a portion of the first electrode AE. In an embodiment, the light-emitting region PXA may be defined to correspond to some regions of the first electrode AE exposed by the pixel opening OPN.

A hole control layer HCL may be disposed in the light-emitting region PXA and the non-light-emitting region NPXA in common. The hole control layer HCL may include a hole transport layer, and further include a hole injection layer. A light-emitting layer EML may be disposed on the hole control layer HCL. The light-emitting layer EML may be disposed in a region corresponding to the pixel opening OPN. That is, the light-emitting layer EML may be formed separately in each of the pixels. However, the inventive concept is not limited thereto, and the light-emitting layer EML may be formed, in common, in a plurality of pixels PX by an open mask.

An electron control layer ECL may be disposed on the light-emitting layer EML. The electron control layer ECL may include an electron transport layer and further include an electron injection layer. The hole control layer HCL and the electron control layer ECL may be formed, in common, in pixels by an open mask. A second electrode CE may be disposed on the electron control layer ECL. The second electrode CE may have an integrated shape and be disposed, in common, in the plurality of pixels. An upper insulating layer TFL may be disposed on the second electrode CE. The upper insulating layer TFL may include a plurality of thin films.

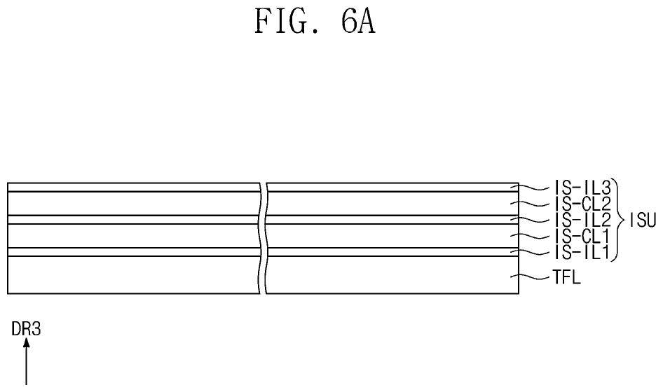

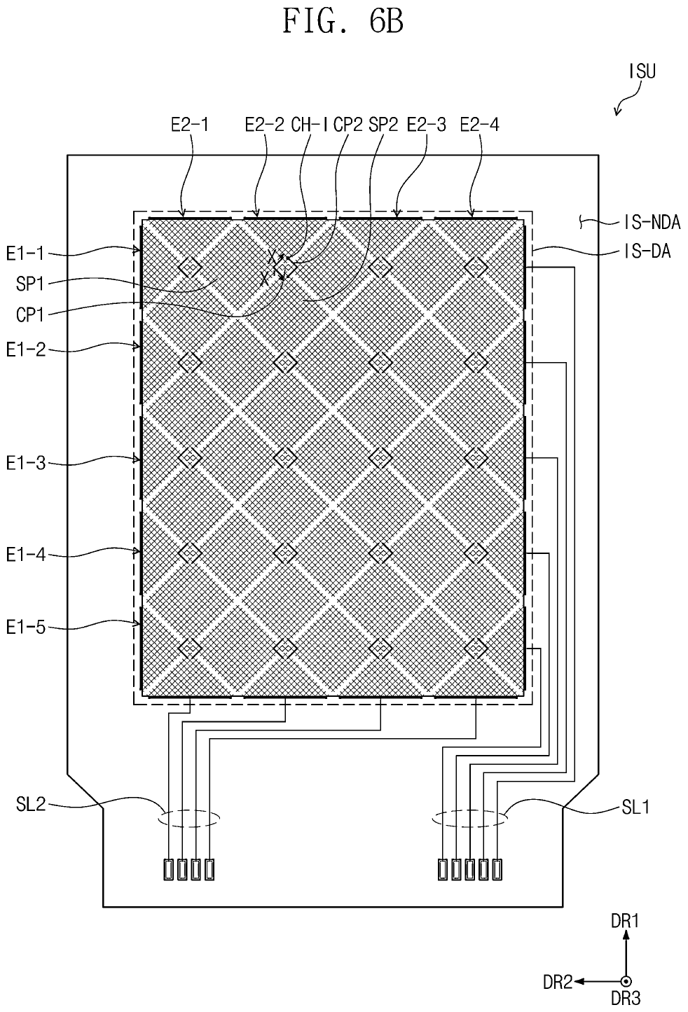

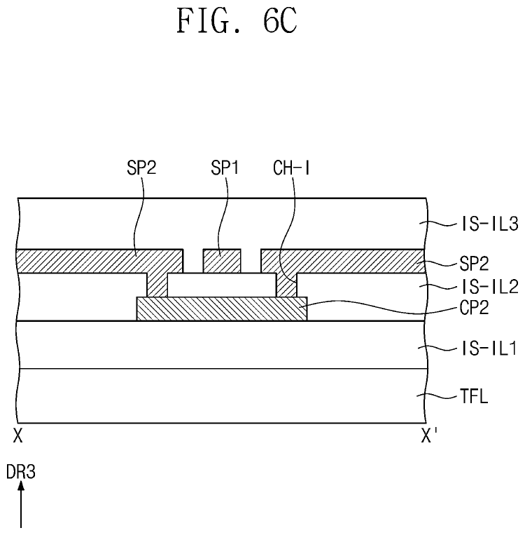

FIG. 6A is a cross-sectional view of an embodiment of an input sensor ISU according to the inventive concept. FIG. 6B is a plan view of an embodiment of an input sensor ISU according to the inventive concept. FIG. 6C is a cross-sectional view of a bridge pattern of an embodiment of an input sensor ISU along line X-X′ of FIG. 6B according to the inventive concept.

The input sensor ISU may include a first insulating layer IS-IL1 (hereinafter, first sensing insulating layer), a first conductive pattern layer IS-CL1, a second insulating layer IS-IL2 (hereinafter, second sensing insulating layer), a second conductive pattern layer IS-CL2, and a third insulating layer IS-IL3 (hereinafter, third sensing insulating layer). The first sensing insulating layer IS-IL1 may be directly disposed on an upper insulating layer TFL.

In an embodiment of the inventive concept, the first sensing insulating layer IS-IL1 and/or the third sensing insulating layer IS-IL3 may be omitted. When the first sensing insulating layer IS-IL1 is omitted, the first conductive pattern layer IS-CL1 may be disposed on the uppermost insulating layer of the upper insulating layer TFL. The third sensing insulating layer IS-IL3 may be replaced with an insulating layer of an anti-reflection member disposed on the adhesive layer or the input sensor ISU.

The first conductive pattern layer IS-CL1 may include first conductive patterns, and the second conductive pattern layer IS-CL2 may include second conductive patterns. Hereinafter, the same reference numerals or symbols are used for the first conductive pattern layer IS-CL1 and the first conductive patterns, and the same reference numerals or symbols are used for the second conductive pattern layer IS-CL2 and the second conductive patterns.

The first conductive patterns IS-CL1 and the second conductive patterns IS-CL2 may each have a single-layered structure or a multi-layered structure in which layers are stacked along the third direction DR3. The multi-layered conductive pattern may include at least two among transparent conductive layers and metal layers. The multi-layered conductive pattern may include metal layers including different metals. The transparent conductive layer may include indium tin oxide (“ITO”), indium zinc oxide (“IZO”), zinc oxide (ZnO), indium tin zinc oxide (“ITZO”), poly(3,4-ethylenedioxythiophene) (“PEDOT”), metal nanowires, and graphene. The metal layer may include molybdenum, silver, titanium, copper, aluminum, and any alloys thereof. A detailed description of a stacked structure of each of the first conductive pattern layer IS-CL1 and the second conductive pattern layer IS-CL2 will be described later.

In this embodiment, the first to third sensing insulating layers IS-IL1, IS-IL2, and IS-IL3 may each include an inorganic layer or an organic layer. In this embodiment, the first to third sensing insulating layers IS-IL1, IS-IL2, and IS-IL3 may include an inorganic layer. The inorganic layer may include silicon oxide, silicon nitride, or silicon oxynitride.

In an embodiment of the inventive concept, at least one among the first to third sensing insulating layers IS-IL1, IS-IL2, and IS-IL3 may be an organic layer. In an embodiment, the third sensing insulating layer IS-IL3 may include an organic layer, for example. The organic layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

Referring to FIGS. 6B and 6C, the input sensor ISU includes a sensing region IS-DA and a non-sensing region IS-NDA adjacent to the sensing region IS-DA. The sensing region IS-DA and the non-sensing region IS-NDA may respectively correspond to the display region DP-DA and the non-display region DP-NDA which are illustrated in FIG. 4.

The input sensor ISU includes a plurality of sensing electrodes disposed in the sensing region IS-DA. The sensing electrodes may include first sensing electrodes E1-1 to E1-5 (hereinafter, first electrodes) and second sensing electrodes E2-1 to E2-4 (hereinafter, second electrodes), which cross each other and are insulated from each other. The input sensor ISU includes first signal lines SL1, electrically connected to the first electrodes E1-1 to E1-5, and second signal lines SL2, electrically connected to the second electrodes E2-1 to E2-4, which are disposed in the non-sensing region IS-NDA. The first electrodes E1-1 to E1-5, the second electrodes E2-1 to E2-4, the first signal lines SL1, and the second signal lines SL2 may be defined as a combination of the first conductive patterns IS-CL1 and the second conductive patterns IS-CL2 described with reference to FIG. 6A.

The first electrodes E1-1 to E1-5 and the second electrodes E2-1 to E2-4 may include a plurality of conductive lines which cross each other and are insulated from each other. A plurality of conductive lines may define a plurality of openings, and the first electrodes E1-1 to E1-5, and the second electrodes E2-1 to E2-4 may each have a mesh shape. The plurality of openings may be defined to respectively correspond to the pixel openings OPN of the pixel-defining layer PDL illustrated in FIG. 5.

Any one among the first electrodes E1-1 to E1-5 and the second electrodes E2-1 to E2-4 may have an integrated shape. In this embodiment, the first electrodes E1-1 to E1-5 having an integrated shape are illustrated. The first electrodes E1-1 to E1-5 may include sensing portions SP1 and middle portions CP1. A portion of the second conductive patterns IS-CL2 described above may correspond to the first electrodes E1-1 to E1-5.

The second electrodes E2-1 to E2-4 may respectively include sensing patterns SP2 and bridge patterns CP2 (or connection patterns). As illustrated in FIGS. 6B and 6C, two adjacent sensing patterns SP2 may be connected to two bridge patterns CP2 via a contact hole CH-I passing through the second sensing insulating layer IS-IL2, but the number of the bridge patterns is not limited. A portion of the second conductive patterns IS-CL2 described above may correspond to the sensing patterns SP2. A portion of the first conductive patterns IS-CL1 described above may correspond to the bridge patterns CP2.

In this embodiment, it is described that the bridge patterns CP2 are formed from the first conductive patterns IS-CL1 illustrated in FIG. 6A, and the first electrodes E1-1 to E1-5 and the sensing patterns SP2 are formed from the second conductive patterns IS-CL2. However, the inventive concept is not limited thereto. As illustrated in FIG. 6A, the first electrodes E1-1 to E1-5 and the sensing patterns SP2 may be formed from the first conductive patterns IS-CL1, and the bridge patterns CP2 may be formed from the second conductive patterns IS-CL2.

Any one among the first signal lines SL1 and the second signal lines SL2 receives a transmission signal for detecting external input from an external circuit, and a remaining one thereof transmits, as a reception signal, capacitance change between the first electrodes E1-1 to E1-5 and the second electrodes E2-1 to E2-4 to an external circuit.

A portion of the second conductive patterns IS-CL2 described above may correspond to the first signal lines SL1 and the second signal lines SL2. The first signal lines SL1 and the second signal lines SL2 may have a structure of a plurality of layers, and include a first layer line, formed from the first conductive patterns IS-CL1 described above, and a second layer line formed from the second conductive patterns IS-CL2 described above. The first layer line and the second layer line may be connected via a contact hole passing through the second sensing insulating layer IS-IL2 (refer to FIG. 6A).

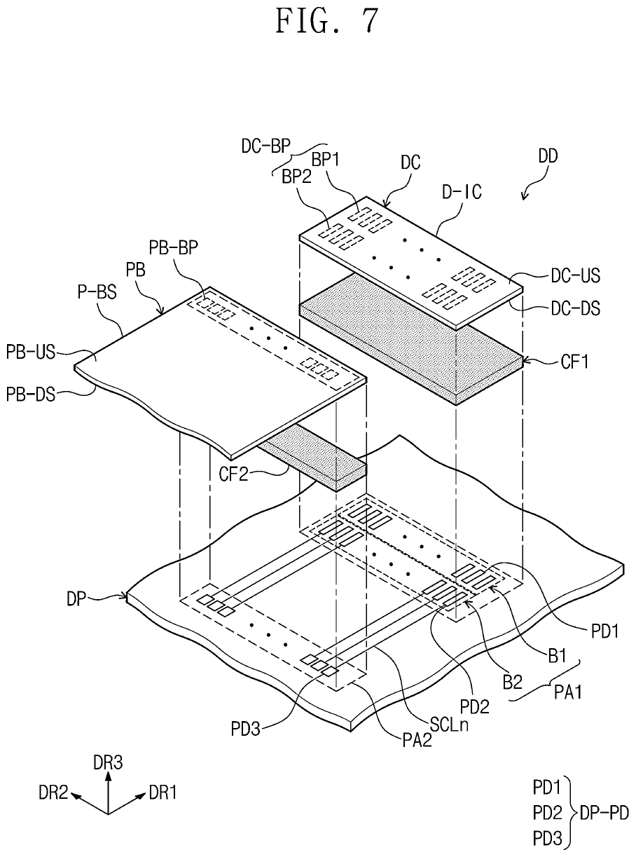

FIG. 7 is an enlarged exploded perspective view of an embodiment of pad regions PA1 and PA2 of a display device DD according to the inventive concept. In an embodiment, FIG. 7 illustrates that a driver chip DC and a circuit board PB are exploded from a display panel DP, for example. First pads PD1, second pads PD2, connection signal lines SCLn, and third pads PD3 which are illustrated in FIG. 7 are identical or similar to the first pads PD1, the second pads PD2, the connection signal lines SCLn, and the third pads PD3 which are illustrated in FIG. 4, and thus the description thereof will be omitted or abbreviated.

Referring to FIGS. 4 and 7, the driver chip DC may be bonded to the first pad region PA1 via a first adhesive layer CF1. The circuit board PB may be bonded to the second pad region PA2 via a second adhesive layer CF2. The first and second adhesive layers CF1 and CF2 may include a synthetic resin with adhesiveness. According to this embodiment, the first and second adhesive layers CF1 and CF2 may not include a conductive ball, and include only a synthetic resin with adhesiveness.

The driver chip DC may include a driving integrated circuit D-IC and chip bump electrodes DC-BP disposed (e.g., mounted) inside the driver chip DC. The driving integrated circuit D-IC may include an upper surface DC-US and a lower surface DC-DS, and the lower surface DC-DS may be a surface facing the first and second pads PD1 and PD2. The chip bump electrodes DC-BP may be disposed on the lower surface DC-DS of the driving integrated circuit D-IC.

The chip bump electrodes DC-BP may include first bumps BP1 electrically connected to the respective first pads PD1 and second bumps BP2 electrically connected to the respective second pads PD2. The first bumps BP1 may be disposed along the second direction DR2, and the second bumps BP2 may be spaced apart from the first bumps BP1 in the first direction DR1 and be disposed along the second direction DR2.

The driver chip DC may receive first signals from the outside via the second pads PD2 and the second bumps BP2. The driver chip DC may provide second signals generated based on the first signals to the first pads PD1 via the first bumps BP1. In an embodiment, the driver chip DC may include a data driving circuit, for example. The first signal may be an image signal which is a digital signal applied from the outside, and the second signal may be a data signal which is an analog signal. The driver chip DC may generate an analog voltage corresponding to a gray level value of an image signal. The data signal may be provided to the pixel PX via the data line DL illustrated in FIG. 4.

Although not illustrated, the first bumps BP1 and the second bumps BP2 may each have a shape protruding from the lower surface DC-DS of the driving integrated circuit D-IC and exposed to the outside. When the first adhesive layer CF1 is cured, the first pads PD1 and the first bumps BP1 may be fixed while being in contact with each other, and the second pads PD2 and the second bumps BP2 may be fixed while being in contact with each other.

The circuit board PB may include a base layer P-BS, and substrate bump electrodes PB-BP disposed (e.g., mounted) inside the circuit board PB. The circuit board PB may include an upper surface PB-US and a lower surface PB-DS, and the lower surface PB-DS may be a surface facing the third pads PD3. The substrate bump electrodes PB-BP may be disposed on the lower surface PB-DS of the base layer P-BS. The substrate bump electrodes PB-BP may be electrically connected to the third pads PD3, respectively. The substrate bump electrodes PB-BP may be arranged along the second direction DR2. The circuit board PB may provide a video signal, a driving voltage, and other control signals to the driver chip DC.

Although not illustrated, the substrate bump electrodes PB-BP may have a shape protruding from the lower surface PB-DS of the base layer P-BS and exposed to the outside. When the second adhesive layer CF2 is cured, the third pads PD3 and the substrate bump electrodes PB-BP may be fixed in a state of being in contact with each other.

An electronic component may include a substrate, and a bump electrode disposed on a lower side of the substrate. When the electronic component corresponds to the driver chip DC, the substrate may correspond to the driving integrated circuit D-IC of the driver chip DC, and the bump electrode may correspond to the chip bump electrode DC-BP. In an alternative embodiment, when the electronic component corresponds to the circuit board PB, the substrate may correspond to the base layer P-BS of the circuit board PB, and the bump electrode may correspond to the substrate bump electrode PB-BP.

FIG. 8A is a schematic plan view of an embodiment of pad regions PA1 and PA2 according to the inventive concept. FIGS. 8B to 8E are plan views illustrating an embodiment of some components inside the pad regions PA1 and PA2 according to the inventive concept.

A signal pad DP-PD illustrated in FIG. 8A (or signal pad structure) may be any one among the first to third pads PD1 to PD3 described with reference to FIGS. 4 and 7. FIG. 8A illustrates, as an embodiment of a signal line, a data line DL including a pad part DL-E and a line part DL-S which have different widths, but the inventive concept is not limited thereto. The signal line may be another signal line other than the data line DL, and the pad part DL-E and the line part DL-S may each have a uniform width.

Referring to FIGS. 8A to 8D, the signal pad DP-PD may include a first conductive pattern CL1 connected to the data line DL, a second conductive pattern CL2 connected to the first conductive pattern CL1, and at least one insulating pattern SP overlapping, in a plan view, the second conductive pattern CL2. FIGS. 8A to 8D illustrate the signal pad DP-PD including four insulating patterns SP. The first conductive pattern CL1 may be connected to the pad part DL-E of the data line DL.

The pad part DL-E, the first conductive pattern CL1, and the second conductive pattern CL2 may be separated according to whether to be disposed with an insulating layer therebetween or whether to be connected via contact holes OP1c and OP2c. In this specification, an insulating layer disposed between the pad part DL-E and the first conductive pattern CL1 is also referred to as a first group insulating layer IG1, and an insulating layer disposed between the first conductive pattern CL1 and the second conductive pattern CL2 is also referred to as a second group insulating layer IG2.

The insulating patterns SP may be disposed to overlap the pad part DL-E. The insulating patterns SP may each include a polymer. The insulating patterns SP may each include a thermosetting polymer. However, the inventive concept is not limited thereto, and the insulating patterns SP may each also include a thermoplastic polymer.

The insulating patterns SP may be aligned in the first direction DR1. FIGS. 8A to 8E illustrate that the insulating patterns SP are aligned in a column (or a row), but the inventive concept is not limited thereto. In an embodiment, the insulating patterns SP may have an arrangement form such that the insulating patterns SP are aligned in both the first direction DR1 and the second direction DR2, for example.

FIGS. 8A to 8E illustrate the insulating patterns SP having a square shape in a plan view, but the inventive concept is not limited thereto. The shapes of the insulating patterns SP may be changed to be circular, oval, or the like. Additionally, the insulating patterns SP may have a quadrangular shape, e.g., rectangular shape extending in one direction, or another polygonal shape. Further, all the insulating patterns SP are not limited to having the same shape.

FIG. 8B is illustrated for the description of the first group insulating layer IG1, and for convenience of description, the data line DL and the insulating patterns SP are also illustrated together.

As illustrated in FIG. 8B, at least one first contact hole OP1c and at least one lower hole OP1r may be defined in the first group insulating layer IG1. The first contact hole OP1c may be also referred to as a first contact opening. The lower hole OP1r may be also referred to as a first reinforcement hole, a first reinforcement opening or a first compensation hole. FIG. 8B illustrates that three first contact holes OP1c and four lower holes OP1r are defined in the first group insulating layer IG1.

The first contact holes OP1c may overlap a partial region of the pad part DL-E. The first group insulating layer IG1 may expose a partial region of the pad part DL-E via the first contact holes OP1c. The first contact holes OP1c may be spaced apart from the insulating patterns SP. That is, in a plan view, the insulating patterns SP may be disposed outside the first contact holes OP1c.

The pad part DL-E may extend in the first direction DR1, and the first contact holes OP1c may be aligned in the first direction DR1. In this embodiment, the insulating patterns SP may be disposed between the first contact holes OP1c. FIGS. 8A to 8D illustrate that two insulating patterns SP aligned in the first direction DR1 are disposed between the adjacent first contact holes OP1c. However, an arrangement form of the insulating patterns SP and the first contact holes OP1c is not limited thereto. In an embodiment, the first contact holes OP1c may be disposed on one side in the first direction DR1, and the insulating patterns SP may be disposed on an opposite side in the first direction DR1, for example. Additionally, the number of the first contact holes OP1c and also the number of the insulating patterns SP are not limited to a particular embodiment.

The lower holes OP1r may respectively overlap the insulating patterns SP. On a plane, the lower holes OP1r may be defined to have a shape corresponding to that of the insulating patterns SP. For convenience of description, FIG. 8B illustrates that an inner side edge, of the first group insulating layer IG1, defining the lower hole OP1r is spaced apart from the insulating pattern SP. However, the insulating pattern SP may be substantially in contact with the inner side edge, of the first group insulating layer IG1, defining the lower hole OP1r. The lower hole OP1r and the insulating pattern SP corresponding to each other may have substantially the same planar area. The insulating patterns SP may each be surrounded by the first group insulating layer IG1.

FIG. 8C is illustrated for the description of the second group insulating layer IG2, and for convenience of description, the pad part DL-E and the insulating patterns SP are also illustrated together. Additionally, for convenience of description, the first contact holes OP1c and the lower holes OP1r are also illustrated together.

As illustrated in FIG. 8C, a second contact hole OP2c may be defined in the second group insulating layer IG2. The second contact hole OP2c may be also referred to as a second contact opening. The second contact holes OP2c may overlap at least a portion of the pad part DL-E. FIG. 8C illustrates that the second contact hole OP2c overlaps an entirety of the pad part DL-E, but the inventive concept is not limited thereto. In an embodiment, the second group insulating layer IG2 may be disposed so as to overlap an outer side portion of the pad part DL-E, and the second contact hole OP2c may be defined so as to overlap an inner side portion of the pad part DL-E, for example.

On a plane, the first contact holes OP1c may be disposed inside the second contact hole OP2c. On a plane, the insulating patterns SP may be disposed inside the second contact hole OP2c.

FIG. 8D is illustrated for the description of the first conductive pattern CL1, and for convenience of description, the pad part DL-E and the insulating patterns SP are also illustrated together. Additionally, for convenience of description, the first and second contact holes OP1c and OP2c are also illustrated together.

As illustrated in FIG. 8D, at least one hole OP2r may be defined in the first conductive pattern CL1. The hole OP2r may be also referred to as a second reinforcement hole, a second reinforcement opening or a second compensation hole. FIG. 8D illustrates that four holes OP2r are defined in the first conductive pattern CL1.

The holes OP2r may respectively overlap the insulating patterns SP. On a plane, the holes OP2r may be defined to have a shape corresponding to that of the insulating patterns SP. For convenience of description, FIG. 8D illustrates that an inner side edge, of the first conductive pattern CL1, defining the hole OP2r is spaced apart from the insulating pattern SP. However, the insulating pattern SP may be substantially in contact with the inner side edge, of the first conductive pattern CL1, defining the hole OP2r. The hole OP2r and the insulating pattern SP corresponding to each other may have substantially the same planar area. The insulating patterns SP may each be surrounded by the first conductive pattern CL1. The holes OP2r may respectively overlap the lower holes OP1r of the first group insulating layer IG1.

The first conductive pattern CL1 may overlap the first contact holes OP1c. The first conductive pattern CL1 may be connected to the pad part DL-E via the first contact holes OP1c.

FIG. 8E is illustrated for the description of the second conductive pattern CL2, and for convenience of description, the pad part DL-E and the insulating patterns SP are also illustrated together. Additionally, for convenience of description, the first and second contact holes OP1c and OP2c, the lower holes OP1r, and the holes OP2r are also illustrated together.

As illustrated in FIG. 8E, the second conductive pattern CL2 may overlap the second contact hole OP2c. The second conductive pattern CL2 may be connected to the first conductive pattern CL1 via the second contact hole OP2c.

The second conductive pattern CL2 may overlap the insulating patterns SP, the lower holes OP1r, and the holes OP2r. The second conductive pattern CL2 may cover the insulating patterns SP.

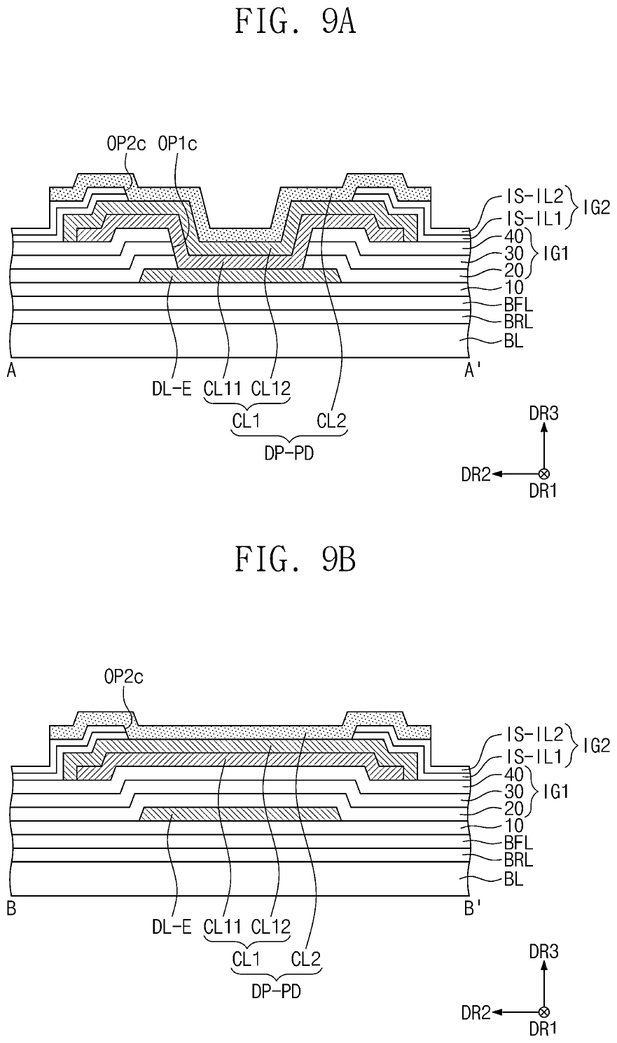

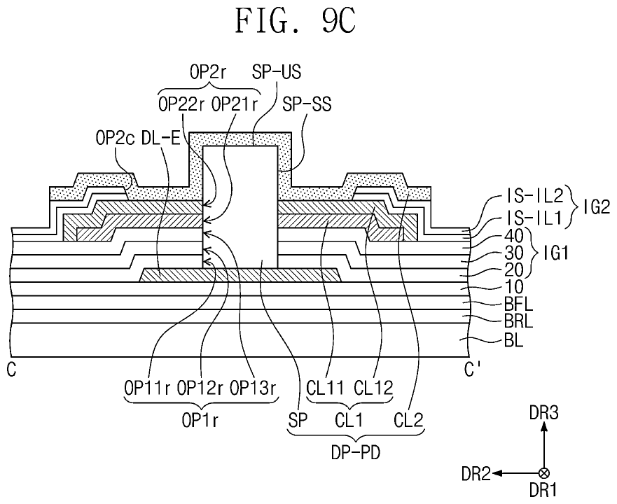

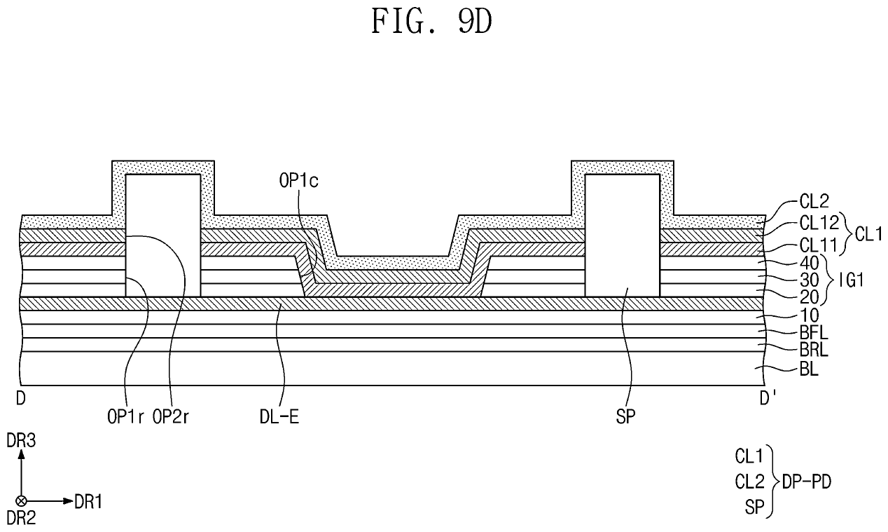

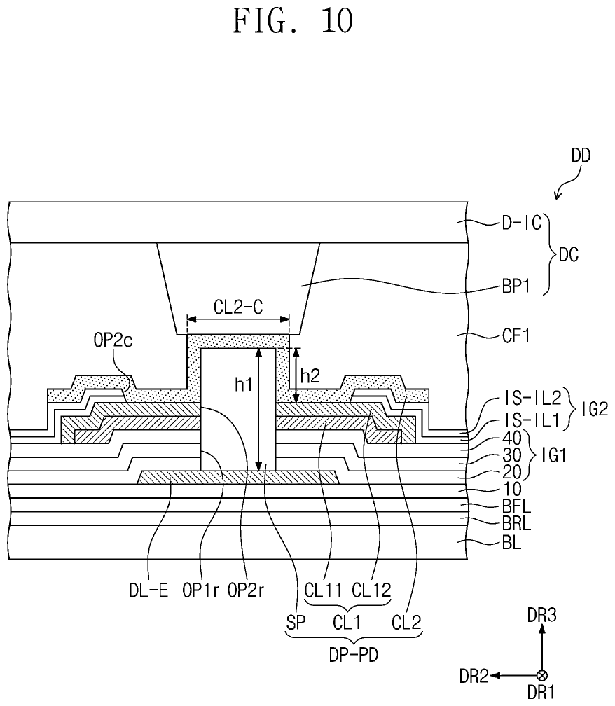

FIGS. 9A to 9D are cross-sectional views corresponding to that of FIG. 8A. FIG. 10 is a cross-sectional view illustrating a bonding structure of a display device DD according to the inventive concept. FIG. 9A is a cross-sectional view of pad regions PA1 and PA2 taken along line A-A′ of FIG. 8A, FIG. 9B is a cross-sectional view of pad regions PA1 and PA2 taken along line B-B′ of FIG. 8A, FIG. 9C is a cross-sectional view of pad regions PA1 and PA2 taken along line C-C′ of FIG. 8A, and FIG. 9D is a cross-sectional view of pad regions PA1 and PA2 taken along line D-D′ of FIG. 8A. The same/similar reference numerals or symbols are used for the components same/similar to those described in FIGS. 1 to 8E. A duplicated description thereof will be omitted, and the following description will be mainly focused on the differences.

Referring to FIGS. 8A to 9D, a pad part DL-E may be disposed on a first insulating layer 10. The pad part DL-E may be disposed in the same layer as the gate G illustrated in FIG. 5. The pad part DL-E and the gate G (refer to FIG. 5) may be formed through the same process. The pad part DL-E may include the same material as that of the gate G.

However, a position of the pad part DL-E is not limited thereto. The pad part DL-E and the upper electrode UE illustrated in FIG. 5 may be disposed in the same layer, include the same material, and also have the same stacked structure. A portion of a plurality of signal lines may be formed through the same process as that for the gate G (refer to FIG. 5), and also another portion thereof may be formed through the same process as that for the upper electrode UE (refer to FIG. 5).

The data line DL may be disposed on one layer and have an integral shape, but the inventive concept is not limited thereto. One data line DL may include a plurality of portions disposed in different layers. In an embodiment, a line part DL-S may include two or more portions, for example.

A first conductive pattern CL1 may be disposed on a fourth insulating layer 40. The first conductive pattern CL1 may be connected to the pad part DL-E via a first contact hole OP1c passing through second to fourth insulating layers 20, 30, and 40. The second to fourth insulating layers 20, 30, and 40 may be formed through the same process as the second to fourth insulating layers 20, 30, and 40 of the display region DP-DA illustrated in FIG. 5. In this embodiment, the second to fourth insulating layers 20, 30, and 40 may be defined as a first group insulating layer IG1. The second insulating layer 20 may be also referred to as a lower insulating layer, the third insulating layer 30 may be also referred to as an intermediate insulating layer, and the fourth insulating layer 40 may be also referred to as an upper insulating layer. A stacked structure of the first group insulating layer IG1 may change according to a stacked structure of a circuit element layer DP-CL. In an embodiment, the first contact hole OP1c may be defined in insulating layers the number of which is more or fewer than the number of the second to fourth insulating layers 20, 30, and 40.

The first conductive pattern CL1 and the pad part DL-E may be separated by the first group insulating layer IG1 disposed therebetween (e.g., second to fourth insulating layers 20, 30, and 40).

The first conductive pattern CL1 may include a first layer CL11 and a second layer CL12. The first layer CL11 and the second layer CL12 may be defined as one conductive pattern since an insulating layer is not disposed therebetween. The first layer CL11 and the second layer CL12 are not connected via a contact hole. The first layer CL11 may be formed through the same process as that for the above-described first connection electrode CNE1 (refer to FIG. 5), and the second layer CL12 may be formed through the same process as that for the above-described second connection electrode CNE2 (refer to FIG. 5). The first layer CL11 and the first connection electrode CNE1 (refer to FIG. 5) may include the same material, and the second layer CL12 and the second connection electrode CNE2 (refer to FIG. 5) may include the same material as each other. FIGS. 9A to 9D illustrate an embodiment in which the first conductive pattern CL1 is disposed on the fourth insulating layer 40. In an embodiment, the first conductive pattern CL1 may be disposed on the third insulating layer 30. In this case, the fourth insulating layer 40 may not be disposed in the pad regions PA1 and PA2. The fifth insulating layer 50 and the sixth insulating layer 60 which are illustrated in FIG. 5 may not be disposed in the pad regions PA1 and PA2. In an embodiment of the inventive concept, any one of the first layer CL11 or the second layer CL12 may be omitted. In an embodiment of the inventive concept, the first conductive pattern CL1 may be omitted.

FIGS. 9A to 9C illustrate that an edge of the second layer CL12 is disposed outside an edge of the first layer CL11 and covers an edge of the first layer CL11, but the inventive concept is not limited thereto. In an embodiment, the first layer CL11 and the second layer CL12 may substantially have the same planar area, and also an edge of the second layer CL12 may be substantially aligned with an edge of the first layer CL11, for example.

A second conductive pattern CL2 may be disposed on a second sensing insulating layer IS-IL2 of the input sensor ISU (refer to FIG. 6A). The second conductive pattern CL2 may be formed through the same process as that for the second conductive pattern layer IS-CL2 of FIG. 6A and the sensing patterns SP2 of FIG. 6C. FIG. 8A illustrates that the second conductive pattern CL2 has a planar area greater than that of the first conductive pattern CL1, and FIGS. 9A to 9C illustrate that an edge of the second conductive pattern CL2 is disposed outside an edge of the first conductive pattern CL1. However, the inventive concept is not limited thereto. The second conductive pattern CL2 and the first conductive pattern CL1 may substantially have the same planar area, and edges of the second conductive pattern CL2 and the first conductive pattern CL1 may also be aligned.

The second conductive pattern CL2 may be connected to the first conductive pattern CL1 via a second contact hole OP2c passing through a first sensing insulating layer IS-IL1 of the input sensor ISU (refer to FIG. 6A), and a second sensing insulating layer IS-IL2 of the input sensor ISU (refer to FIG. 6A). In this embodiment, the first sensing insulating layer IS-IL1 and the second sensing insulating layer IS-IL2 may be defined as a second group insulating layer IG2. The first sensing insulating layer IS-IL1 and the second sensing insulating layer IS-IL2 may overlap the sensing region IS-DA and the non-sensing region IS-NDA which are illustrated in FIG. 6B. Accordingly, the first sensing insulating layer IS-IL1 and the second sensing insulating layer IS-IL2 may overlap the pad regions PA1 and PA2.

The second conductive pattern CL2 and the first conductive pattern CL1 may be separated by the second group insulating layer IG2 disposed therebetween (e.g., first sensing insulating layer IS-IL1 and second sensing insulating layer IS-IL2). In an embodiment of the inventive concept, any one of the first sensing insulating layer IS-IL1 or the second sensing insulating layer IS-IL2 may be omitted.

As illustrated in FIGS. 9A and 9D, the first conductive pattern CL1 may contact a pad part DL-E via a first contact hole OP1c. An area of the first contact hole OP1c may determine a contact area of the first conductive pattern CL1 and the pad part DL-E. As illustrated in FIGS. 9A to 9D, a portion, of the first conductive pattern CL1, not overlapping the first contact hole OP1c may be disposed on the first group insulating layer IG1 (e.g., fourth insulating layer 40).

As illustrated in FIGS. 9A to 9D, a portion, of the second conductive pattern CL2, overlapping the second contact hole OP2c may be disposed on the first conductive pattern CL1. The second conductive pattern CL2 may contact the first conductive pattern CL1 via the second contact hole OP2c. A portion, of the second conductive pattern CL2, not overlapping the second contact hole OP2c may be disposed on the second group insulating layer IG2 (e.g., second sensing insulating layer IS-IL2). The second group insulating layer IG2 (e.g., first and second sensing insulating layers IS-IL1 and IS-IL2) may be disposed between a portion, of the second conductive pattern CL2, not overlapping the second contact hole OP2c and a portion of the first conductive pattern CL1.

As illustrated in FIGS. 9C and 9D, a portion, of the second conductive pattern CL2, overlapping the second contact hole OP2c, may include a portion overlapping an insulating pattern SP (or, first and second compensation holes OP1r and OP2r). In a cross-section, the insulating pattern SP may be disposed between the pad part DL-E and the second conductive pattern CL2. A portion, of the second conductive pattern CL2, overlapping the insulating pattern SP may not contact and be spaced apart from the first conductive pattern CL1.

The insulating pattern SP may be directly disposed on the pad part DL-E. As illustrated in FIG. 9D, a portion, of the pad part DL-E, overlapping the first contact hole OP1c may contact the first conductive pattern CL1. A portion, of the pad part DL-E, not overlapping the first contact hole OP1c and overlapping the lower holes OP1r and the holes OP2r may contact the insulating pattern SP, and a portion, of the pad part DL-E, not overlapping the first contact hole OP1c, the lower holes OP1r, and the holes OP2r may contact the first group insulating layer IG1.

The insulating pattern SP may be formed through the same process as that for at least any one of the sixth insulating layer 60 or the pixel-defining layer PDL which is illustrated in FIG. 5. The insulating pattern SP may be formed through the same process as that for the pixel-defining layer PDL illustrated in FIG. 5. According to this embodiment, an additional process for forming the insulating pattern SP is not desired.

In this embodiment, a lower hole OP1r defined in the first group insulating layer IG1 may include a first lower hole OP11r defined in the second insulating layer 20, a second lower hole OP12r defined in the third insulating layer 30, and a third lower hole OP13r defined in the fourth insulating layer 40. The first to third lower holes OP11r, OP12r, and OP13r may define an integrated opening space. The first to third lower holes OP11r, OP12r, and OP13r may be respectively defined by inner side surfaces of the second to fourth insulating layers 20, 30, and 40, and the inner side surfaces of the second to fourth insulating layers 20, 30, and 40 may be substantially aligned. The insulating pattern SP may be disposed to pass through the first group insulating layer IG1 via the lower hole OP1r.

In this embodiment, a hole OP2r defined in the first conductive pattern CL1 may include a first hole OP21r defined in the first layer CL11 and a second hole OP22r defined in the second layer CL12. The first and second holes OP21r and OP22r may define an integrated opening space. The first and second holes OP21r and OP22r may be respectively defined by inner side surfaces of the first and second layers CL11 and CL12, and the inner side surfaces of the first and second layers CL11 and CL12 may be substantially aligned. The hole OP2r and the lower hole OP1r may define an integrated opening space. A planar area of the hole OP2r may be substantially the same as a planar area of the lower hole OP1r. The insulating pattern SP may be disposed to pass through the first conductive pattern CL1 via the hole OP2r.

A portion of a side surface SP-SS of the insulating pattern SP may be surrounded by the first group insulating layer IG1 and the first conductive pattern CL1. A portion of the side surface SP-SS of the insulating pattern SP may contact the first group insulating layer IG1 and the first conductive pattern CL1. An upper surface SP-US and the remaining portion of the side surface SP-SS of the insulating pattern SP may be surrounded by the second conductive pattern CL2. The upper surface SP-US and the remaining portion of the side surface SP-SS of the insulating pattern SP may contact the second conductive pattern CL2.

The insulating pattern SP may have a quadrangular shape, e.g., rectangular shape in a cross-section. However, the inventive concept is not limited thereto, and the insulating pattern SP may have a trapezoidal shape in which the side surfaces are inclined.

In FIG. 10, a driver chip DC is illustrated as an electronic component. FIG. 10 illustrates that a first bump BP1 of the chip bump electrodes DC-BP (refer to FIG. 7) of the driver chip DC contacts a contact portion CL2-C of a second conductive pattern CL2. The contact portion CL2-C of the second conductive pattern CL2 may protrude from a second sensing insulating layer IS-IL2 due to an insulating pattern SP, compared to another portion of the second conductive pattern CL2. The contact portion CL2-C of the second conductive pattern CL2 may protrude from the first conductive pattern CL1 toward a direction of getting farther away from a pad part DL-E.

Due to a bonding pressure, the first bump BP1 of the driver chip DC may pass through a first adhesive layer CF1 to contact the contact portion CL2-C of the second conductive pattern CL2. The first adhesive layer CF1 before being cured may have a lower viscosity than an anisotropic conductive film. In order to induce an alignment of conductive balls, an anisotropic conductive film has a relatively high viscosity.

Since the contact portion CL2-C of the second conductive pattern CL2 protrudes toward the first bump BP1, the contact portion CL2-C and the first bump BP1 may be in close contact with each other, and thus contact resistance therebetween may be reduced. A conductive ball is omitted, and the proximity between the signal pad DP-PD and the first bump BP1 is improved. Therefore, a bonding pressure may be reduced. Due to the reduced bonding pressure, the occurrence of physical damages of the display panel DP (FIG. 7) or electronic components during a bonding process may be reduced.

In an embodiment, a portion of the insulating pattern SP may be surrounded by the first conductive pattern CL1 and the first group insulating layer IG1, and during the process in which a bonding pressure is applied, a side portion of a part of the insulating pattern SP may be reinforced via the first conductive pattern CL1 and the first group insulating layer IG1. More specifically, a degree of deformation caused by a bonding pressure may be relatively small in a portion, of the insulating pattern SP, surrounded by the first conductive pattern CL1 and the first group insulating layer IG1. Accordingly, a bonding pressure may be intensively transmitted to a portion, of the insulating pattern SP, protruding from the first conductive pattern CL1. In this manner, an adhesiveness between the second conductive pattern CL2 and the insulating pattern SP increases, and thus the second conductive pattern CL2 may be further in close contact with the bump electrode (e.g., first bump BP1). Additionally, the protruding portion of the insulating pattern SP may be greatly deformed due to a bonding pressure, and thus a contact area between the second conductive pattern CL2 and the bump electrode may increase. Therefore, the display device DD, in which bonding defects and bonding resistance are reduced, may be provided.

When the insulating pattern has a height of a predetermined level or lower in a case where a side portion of a part of an insulating pattern is not reinforced, a bonding pressure is more intensively transmitted, and thus the second conductive pattern may be in close contact with the bump electrode, so that a contact area between the second conductive pattern and the bump electrode may become sufficient. When the insulating pattern has a height greater than a predetermined level in a case where a side portion of a part of the insulating pattern is not reinforced, a center portion may be deformed, during a process of applying a bonding pressure, due to insufficient supporting force of the insulating pattern. In an embodiment, the insulating pattern may be not only pressed vertically, but also bent laterally, for example. In this case, an adhesiveness between the insulating pattern and the second conductive pattern is reduced, and thus bonding defects may occur. Also, the contact area between the second conductive pattern and the bump electrode becomes insufficient, resulting in an increase in contact resistance. In an embodiment, the predetermined level of height may be about 1 micrometer, for example. However, since precise manufacturing is desired for insulation patterns to satisfy a predetermined level of height or lower, there may be difficulties in performing a process.

According to the inventive concept, although the insulating pattern SP has a first height h1, a portion to which a bonding pressure is substantially transmitted may have a second height h2 smaller than the first height h1. Therefore, when the second height h2 satisfies a height of the predetermined level or lower, a bonding structure with reduced bonding defects and contact resistance may be achieved. Additionally, when the insulating pattern SP is manufactured to have the first height h1 higher than the second height h2, issues occurring during the process may be overcome. In an embodiment, the first height h1 may be about three times the second height h2. Therefore, it is possible to not only resolve difficulties in performing a process, but also provide the display device DD with improved bonding reliability.

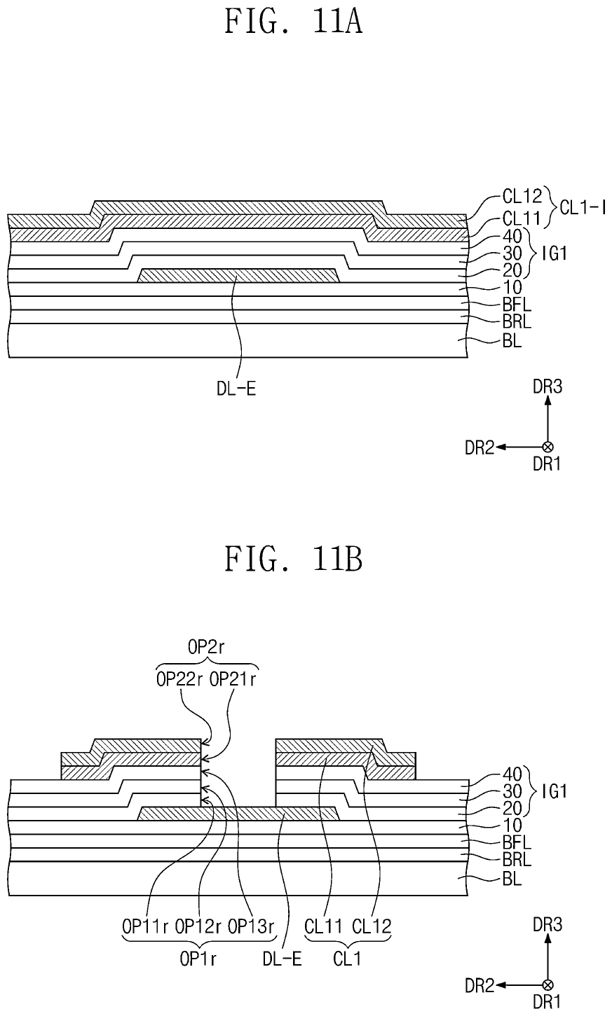

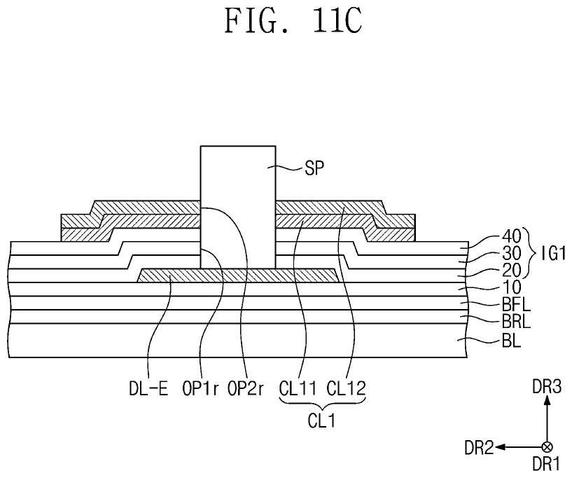

FIGS. 11A to 11C are cross-sectional views which illustrate some operations of a method of manufacturing a display device according to the inventive concept. The same/similar reference numerals or symbols are used for the components same/similar to those described in FIGS. 8A to 10. A duplicated description thereof will be omitted and the following description will be mainly focused on the differences.

Referring to FIG. 11A, the method of manufacturing the display device in an embodiment of the inventive concept may include depositing a first group insulating layer IG1, and depositing a first preliminary conductive pattern CL1-I.

The first group insulating layer IG1 may be disposed on a first insulating layer 10. The first group insulating layer IG1 may be formed to cover a pad part DL-E. In this embodiment, the depositing of the first group insulating layer IG1 may include depositing a second insulating layer 20, depositing a third insulating layer 30, and depositing a fourth insulating layer 40.

The first preliminary conductive pattern CL1-I may be deposited on the first group insulating layer IG1. The first preliminary conductive pattern CL1-I may be a conductive layer. In this embodiment, the depositing of the first preliminary conductive pattern CL1-I may include depositing a first layer CL11, and depositing a second layer CL12 on the first layer CL11.

Referring to FIGS. 11A and 11B, the method of manufacturing the display device in an embodiment of the inventive concept may include forming the first conductive pattern CL1 having a hole OP2r defined therein by patterning the first preliminary conductive pattern CL1-I. The forming of the first conductive pattern CL1 may be performed through photolithography and etching processes.

In this embodiment, the first conductive pattern CL1 may include the first layer CL11 and the second layer CL12. A first hole OP21r may be defined in the first layer CL11, a second hole OP22r may be defined in the second layer CL12, and the first hole OP21r and the second hole OP22r may define an integrated opening space. In this embodiment, the hole OP2r may correspond to an integrated opening space defined by the first hole OP21r and the second hole OP22r.

Additionally, the method of manufacturing the display device in an embodiment of the inventive concept may include forming a lower hole OP1r in the first group insulating layer IG1.

A first lower hole OP11r may be defined in the second insulating layer 20, a second lower hole OP12r may be defined in the third insulating layer 30, a third lower hole OP13r may be defined in the fourth insulating layer 40, and the first to third lower holes OP11r, OP12r, and OP13r may define an integrated opening space. In this embodiment, the lower hole OP1r may correspond to an integrated opening space defined by the first to third lower holes OP11r, OP12r, and OP13r. Additionally, the lower hole OP1r and the hole OP2r may define an integrated opening space. The forming of the lower hole OP1r may be performed through photolithography and etching processes.

Since in an actual process, a relatively large hole and a relatively small pattern may be formed due to equipment tolerances, a hole may be designed to be smaller than a set target width value, and a pattern may be designed to be larger than a set target width value. In consideration of the above, when it is set to manufacture an insulating pattern SP (refer to FIG. 11C) having a first width, the lower hole OP1r and the hole OP2r may each be set to have a second width smaller than the first width by about 0.1 micrometer to about 1.0 micrometer.

Referring to FIG. 11C, the method of manufacturing the display device in an embodiment of the inventive concept may include forming the insulating pattern SP.

In this embodiment, the forming of the insulating pattern SP may be performed after forming the first conductive pattern CL1. A portion of the insulating pattern SP may be disposed inside the lower hole OP1r and the hole OP2r. The insulating pattern SP may be disposed inside the lower hole OP1r and the hole OP2r and pass through the first group insulating layer IG1 and the first conductive pattern CL1. Additionally, the insulating pattern SP may be formed to further protrude from the first conductive pattern CL1 to an upper side. The portion, of the insulating pattern SP, protruding from the first conductive pattern CL1 may provide the contact portion CL2-C (refer to FIG. 10) of the second conductive pattern CL2 to be formed later.

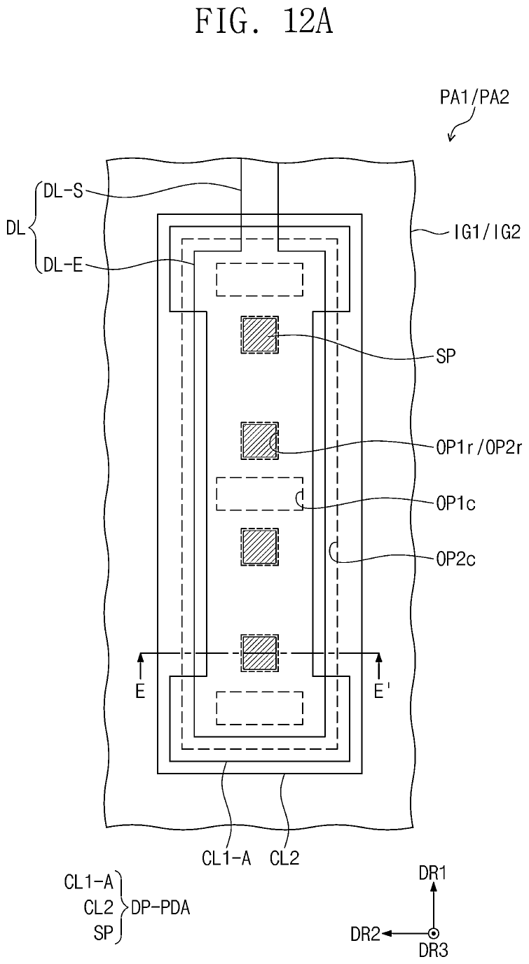

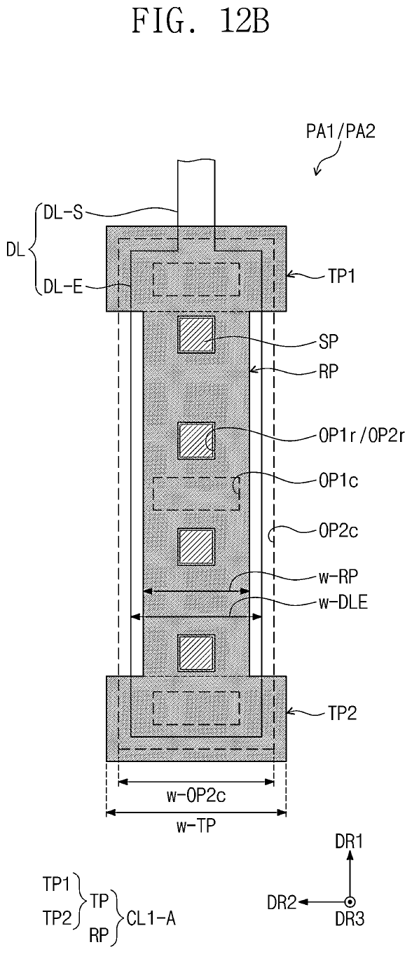

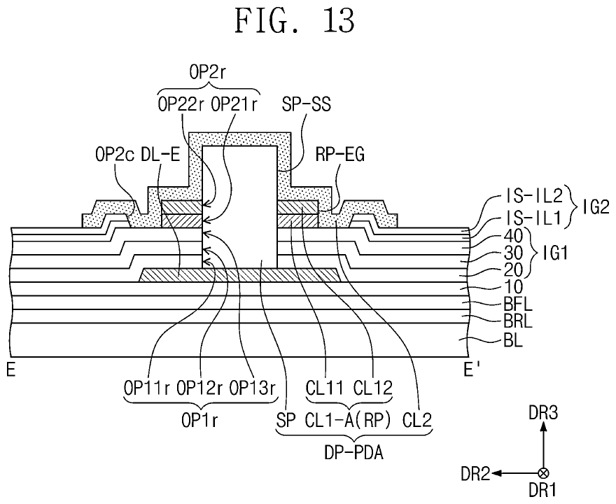

FIG. 12A is a schematic plan view of pad regions PA1 and PA2 according to the inventive concept. FIG. 12B is a plan view illustrating some components inside pad regions PA1 and PA2 according to the inventive concept. FIG. 13 is a cross-sectional view corresponding to that of FIG. 12A. FIG. 12B is illustrated for the description of a first conductive pattern CL1-A, and for convenience of description, a data line DL, insulating patterns SP, first and second contact holes OP1c and OP2c are also illustrated together. FIG. 13 is a cross-sectional view of pad regions PA1 and PA2 taken along line E-E′ of FIG. 12A. The same/similar reference numerals or symbols are used for the components same/similar to those described in FIGS. 1 to 11C. A duplicated description thereof will be omitted, and the following description will be mainly focused on the differences.

Referring to FIGS. 12A and 12B, a signal pad DP-PDA may include a first conductive pattern CL1-A, a second conductive pattern CL2, and at least one insulating pattern SP. The first conductive pattern CL1-A according to this embodiment may include at least one contact portion TP and at least one recessed portion RP. FIGS. 12A and 12B illustrate that two contact portions TP and one recessed portion RP are included.

The contact portions TP may each be a portion overlapping at least a portion of the first contact holes OP1c. In an embodiment, the contact portions TP may include a first contact portion TP1 and a second contact portion TP2. The first contact portion TP1 may be a portion overlapping a first contact hole, among the first contact holes OP1c, disposed on one side in the first direction DR1, and the second contact portion TP2 may be a portion overlapping a first contact hole, among the first contact holes OP1c, disposed on an opposite side in the first direction DR1.

The recessed portion RP may be a portion overlapping insulating patterns SP. In an embodiment, the recessed portion RP may be disposed between the first contact portion TP1 and the second contact portion TP2, and the first contact portion TP1 and the second contact portion TP2 may be spaced apart from each other with the recessed portion RP therebetween in the first direction DR1. The recessed portion RP may extend from the first contact portion TP1 to the second contact portion TP2 in the first direction DR1.

FIGS. 12A and 12B illustrate that the first conductive pattern CL1-A includes one recessed portion RP, and the recessed portion RP overlaps all of four insulating patterns SP and also overlaps the first contact hole OP1c disposed between the insulating patterns SP. However, the inventive concept is not limited thereto, and the first conductive pattern CL1-A may also further include an additional contact portion overlapping the first contact hole OP1c disposed between the insulating patterns SP. The recessed portion RP may be provided in plural.

In this embodiment, the width w-RP of the recessed portion RP in the second direction DR2 may be smaller than the width w-TP of the contact portions TP in the second direction DR2. The recessed portion RP and the contact portions TP may be distinguished in terms of a width in the second direction DR2.

The width w-TP of each of the contact portions TP in the second direction DR2 may be greater than the width w-DLE of the pad part DL-E in the second direction DR2 whereas the width w-RP of the recessed portion RP in the second direction DR2 may be smaller than the width w-DLE of the pad part DL-E in the second direction DR2. On a plane, a portion of the pad part DL-E may not overlap the first conductive pattern CL1-A.

The width w-RP of the recessed portion RP in the second direction DR2 may be smaller than the width w-OP2c of the second contact hole OP2c in the second direction DR2. The recessed portion RP may not include a portion covered by a second group insulating layer IG2.

The contact portions TP are portions connected to the pad part DL-E via the first contact hole OP1c, and may be provided to have a relatively larger width than a width of the recessed portion RP so as to provide a sufficient area for connection stability.

The recessed portion RP is a portion surrounding the insulating pattern SP, and may be provided to have a relatively smaller width than a width of the contact portions TP such that the recessed portion RP may be re-surrounded by the second conductive pattern CL2. The details thereof will be described later.

Referring to FIGS. 12A, 12B, and 13, a portion of the first conductive pattern CL1-A, that is, the recessed portion RP may be disposed inside the second contact hole OP2c. Since the recessed portion RP is not covered by the second group insulating layer IG2 and has a smaller width than a width of the second conductive pattern CL2, an outer side surface RP-EG of the first conductive pattern CL1-A in the recessed portion RP may contact the second conductive pattern CL2 and covered by the second conductive pattern CL2. Accordingly, the second conductive pattern CL2 may cover the recessed portion RP in a dome shape. That is, a portion of a side surface SP-SS of the insulating pattern SP may be surrounded by the recessed portion RP, and the outer side surface RP-EG of the first conductive pattern CL1-A in the recessed portion RP may be surrounded by the second conductive pattern CL2. As illustrated in FIG. 13, in a cross-section, the second conductive pattern CL2 may contact a portion, of the outer side surface RP-EG of the first conductive pattern CL1, opposed to an inner side surface which defines the hole OP2r.

In a process of applying a bonding pressure, a portion of the side surface SP-SS of the insulating pattern SP may be supported by both the recessed portion RP and the second conductive pattern CL2. Therefore, in the process of applying the bonding pressure, a part of a side portion of the insulating pattern SP may be more strongly supported, and a bonding pressure may be more easily transmitted to a protruding portion of the insulating pattern SP.

According to the inventive concept, an insulating pattern disposed on a signal pad of a display panel may be protruded toward an electronic component by a conductive pattern of the signal pad. The display panel and the electronic component may be bonded without an anisotropic conductive film. Even when the signal pads are densely disposed in a pad part, a short defect caused by a conductive ball may be reduced. Additionally, a conductive ball is omitted, and accessibility between the signal pad of the display panel and a bump electrode of the electronic component is improved, and thus a bonding pressure may be reduced. The bonding pressure may be reduced, thereby reducing the occurrence of physical damages in the display panel or electronic components during a bonding process.

According to the inventive concept, since a side portion of a part of an insulating pattern is reinforced, a bonding pressure may be intensely transmitted to the remaining portion of the insulating pattern. Therefore, since a conductive pattern of a signal pad is further in close contact with a bump electrode of an electronic component, a contact area between the conductive pattern and the bump electrode is increased, and thus bonding defects and bonding resistance may be reduced. Furthermore, the insulating pattern may be manufactured at a height sufficient to prevent issues occurring during a process. That is, it is possible to not only resolve difficulties in performing a process, but also provide the display device with improved bonding reliability.

Although the embodiments of the inventive concept have been described, it is understood that the inventive concept should not be limited to these embodiments but various changes and modifications may be made by one ordinary skilled in the art within the spirit and scope of the inventive concept as hereinafter claimed. Therefore, the technical scope of the inventive concept is not limited to the contents described in the detailed description of the specification, but should be determined by the claims.

What is claimed is:

1. A display device comprising a display module, the display module including:
a pixel,
a signal line including a line part and a pad part extending from one end of the line part, and electrically connected to the pixel, and
a signal pad connected to the signal line, the signal pad including:
a first conductive pattern disposed on the pad part,
a second conductive pattern disposed on the first conductive pattern, and
an insulating pattern which, in a cross-section, is disposed between the pad part and the second conductive pattern, and in a plan view, overlaps the second conductive pattern,
wherein a hole overlapping the insulating pattern in the plan view is defined in the first conductive pattern, and the insulating pattern passes through the first conductive pattern via the hole.

2. The display device of claim 1, wherein a portion of a side surface of the insulating pattern contacts the first conductive pattern.

3. The display device of claim 1, wherein the insulating pattern protrudes, from the first conductive pattern, toward a direction of getting farther away from the pad part.

4. The display device of claim 1, wherein the first conductive pattern has a structure of a plurality of layers.

5. The display device of claim 1, wherein the second conductive pattern contacts at least a portion of an upper surface of the first conductive pattern, and a portion, of the insulating pattern, exposed from the first conductive pattern.

6. The display device of claim 5, wherein in the cross-section, the second conductive pattern further contacts a portion, of an outer side surface of the first conductive pattern, opposed to an inner side surface which defines the hole.

7. The display device of claim 1, wherein the display module further comprises a first group insulating layer disposed between the pad part of the signal line and the first conductive pattern,
a lower hole overlapping the hole in the plan view is defined in the first group insulating layer, and the insulating pattern passes through the first group insulating layer via the lower hole.

8. The display device of claim 7, wherein the insulating pattern contacts a region, of the pad part of the signal line, overlapping the lower hole in the plan view.

9. The display device of claim 1, wherein the display module further comprises a first group insulating layer disposed between the pad part of the signal line and the first conductive pattern,
a first contact hole, which, in the plan view, overlaps the pad part of the signal line and is spaced apart from the insulating pattern, is defined in the first group insulating layer, and
the first conductive pattern contacts the pad part of the signal line via the first contact hole.

10. The display device of claim 9, wherein the first conductive pattern comprises a contact portion and a recessed portion having a smaller width than a width of the contact portion in one direction,
the first contact hole overlaps the contact portion, and
the hole is defined in the recessed portion.

11. The display device of claim 9, wherein the display module further comprises a second group insulating layer disposed between the first conductive pattern and the second conductive pattern, and having a second contact hole defined therein, and
in the plan view, the first contact hole and the insulating pattern are disposed inside the second contact hole.

12. The display device of claim 9, wherein the pixel comprises:
a light-emitting element;
a transistor electrically connected to the light-emitting element and including a semiconductor pattern and a gate overlapping the semiconductor pattern;
an upper electrode disposed on the gate; and
a plurality of connection electrodes electrically connected to the transistor and disposed in different layers, and
the pad part of the signal line comprises a same material as a material of the gate or the upper electrode, and
the first conductive pattern comprises a same material as at least one of the plurality of connection electrodes.

13. The display device of claim 12, wherein the display module further comprises:
a lower insulating layer disposed between the semiconductor pattern and the gate;
an intermediate insulating layer disposed between the gate and the upper electrode; and
an upper insulating layer disposed between the upper electrode and the plurality of connection electrodes, and
the first group insulating layer comprises the lower insulating layer, the intermediate insulating layer, and the upper insulating layer.

14. The display device of claim 12, wherein the display module further comprises:
a thin-film encapsulation layer disposed on the pixel; and
a sensing electrode disposed on the thin-film encapsulation layer, and
the second conductive pattern comprises a same material as a material of the sensing electrode.

15. The display device of claim 14, wherein the display module further comprises a second group insulating layer disposed between the first conductive pattern and the second conductive pattern, and
the second conductive pattern and the sensing electrode contact the second group insulating layer.

16. The display device of claim 1, wherein the insulating pattern is provided in plural,
a plurality of holes is provided in the first conductive pattern, and
the plurality of holes respectively overlaps insulating patterns in the plan view.

17. The display device of claim 1, wherein the insulating pattern comprises a polymer.

18. The display device of claim 1, further comprising:
an electronic component electrically connected to the display module; and
an adhesive layer disposed between the display module and the electronic component,
wherein a portion, of the second conductive pattern, overlapping the insulating pattern contacts the electronic component.

19. The display device of claim 18, wherein the electronic component comprises a substrate, and a bump electrode disposed below the substrate, and
a portion, of the second conductive pattern, overlapping the insulating pattern contacts the bump electrode.

20. The display device of claim 18, wherein the electronic component comprises a driver chip or a circuit board.
